(19) United States
(12) Patent Application Publication
(10) Pub. No.: US 2023/0247880 A1
(43) Pub. Date: Aug. 3, 2023

(54) ELECTRO-OPTICAL DEVICE AND ELECTRONIC APPARATUS

(71) Applicant: SEIKO EPSON CORPORATION, Tokyo (JP)

(72) Inventor: Takumi KODAMA, Chino-shi (JP)

(73) Assignee: SEIKO EPSON CORPORATION, Tokyo (JP)

(21) Appl. No.: 18/162,351

(22) Filed: Jan. 31, 2023

(30) Foreign Application Priority Data
Feb. 1, 2022 (JP) 2022-014030

(51) Int. Cl. H10K 59/131; G09G 3/3233

(52) U.S. Cl. CPC H10K 59/1315; G09G 3/3233; G09G 2300/0842; G09G 2300/0819; G09G 2310/08; G09G 2300/0814; G09G 2300/0828

(57) ABSTRACT

An electro-optical device includes a substrate provided with a transistor, a plurality of wires that are provided in a plurality of wiring layers between the substrate and a pixel electrode in a Z direction, and are used by the transistor to supply current to a light-emitting element, a scanning line that is provided in a wiring layer and extends in an X direction, and a data line that is provided in a wiring layer and extends in a Y direction. A wire provided in the wiring layer extends in the X direction, and a wire provided in the wiring layer extends in the Y direction.

The present application is based on, and claims priority from JP Application Serial Number 2022-014030, filed Feb. 1, 2022, the disclosure of which is hereby incorporated by reference herein in its entirety.

### BACKGROUND

### 1. Technical Field

The present disclosure relates to an electro-optical device and an electronic apparatus.

### 2. Related Art

An electro-optical device has been known that uses an organic light emitting diode (OLED) as a light-emitting element for example. In the electro-optical device, a pixel circuit including a transistor or the like that makes current flow in the light-emitting element is provided corresponding to each pixel of an image to be displayed.

Higher resolution and definition require a shorter distance between adjacent pixel circuits and various wires. For example, when the distance between two wires is short, a change in voltage caused by one of the wires is likely to affect the other one of the wires, and thus interference is likely to occur.

In view of this, a technique of suppressing interference in a direction orthogonal to a scanning line has been proposed (see, for example, JP-A-2018-124540). This is achieved with a power supply wire for supplying current to the light-emitting element provided in the same wiring layer as the scanning line, to extend in the same direction as the scanning line.

In recent years, electro-optical devices have been demanded to have even high resolution and definition. Thus, miniaturization of the electro-optical devices cannot be fully achieved by simply suppressing the interference in the direction orthogonal to the scanning line.

### SUMMARY

An electro-optical device according to one aspect of the present disclosure includes a substrate provided with a first transistor, a light-emitting element including a pixel electrode, a plurality of power supply wires that are provided in a plurality of wiring layers between the substrate and the pixel electrode in a thickness direction of the substrate, and are used by the first transistor to supply current to the light-emitting element, a scanning line that is provided in a first wiring layer of the plurality of wiring layers and extends in a first direction, and a data line that is provided in a second wiring layer of the plurality of wiring layers and extends in a second direction, in which the plurality of power supply wires include a first power supply wire and a second power supply wire, the first power supply wire is provided in the first wiring layer and extends in the first direction, and the second power supply wire is provided in the second wiring layer and extends in the second direction.

### BRIEF DESCRIPTION OF THE DRAWINGS

FIG. 1 is a perspective view illustrating an electro-optical device according to an embodiment.

FIG. 2 is a block diagram illustrating a configuration of a main part of the electro-optical device.

FIG. 3 is a circuit diagram illustrating a configuration of the main part of the electro-optical device.

FIG. 4 is a diagram illustrating a configuration of a pixel circuit in a display region.

FIG. 5 is a timing chart illustrating an operation of the electro-optical device.

FIG. 6 is a timing chart illustrating an operation of the electro-optical device.

FIG. 7 is a diagram for illustrating an operation of the electro-optical device.

FIG. 8 is a diagram for illustrating an operation of the electro-optical device.

FIG. 9 is a diagram for illustrating an operation of the electro-optical device.

FIG. 10 is a diagram for illustrating an operation of the electro-optical device.

FIG. 11 is a diagram for illustrating an operation of the electro-optical device.

FIG. 12 is a diagram for illustrating an operation of the electro-optical device.

FIG. 13 is a cross-sectional view of a main part of the electro-optical device.

FIG. 14 is a plan view illustrating a semiconductor layer and the like in the electro-optical device.

FIG. 15 is a plan view illustrating a wire including a first wiring layer and the like in the electro-optical device.

FIG. 16 is a plan view illustrating a wire including a second wiring layer and the like in the electro-optical device.

FIG. 17 is a plan view illustrating a wire including a third wiring layer and the like in the electro-optical device.

FIG. 18 is a plan view illustrating a wire including a fourth wiring layer and the like in the electro-optical device.

FIG. 19 is a plan view illustrating a pixel electrode in the electro-optical device.

FIG. 20 is a plan view illustrating a light-emitting region in the electro-optical device.

FIG. 21 is a cross-sectional view of a main part of a red light-emitting region in the electro-optical device.

FIG. 22 is a cross-sectional view of a main part of a green light-emitting region in the electro-optical device.

FIG. 23 is a cross-sectional view of a main part of a blue light-emitting region in the electro-optical device.

FIG. 24 is a plan view illustrating a wire including a fourth wiring layer and the like according to a modification.

FIG. 25 is a plan view illustrating a pixel electrode according to the modification.

FIG. 26 is a plan view illustrating a light-emitting region according to the modification.

FIG. 27 is a plan view of the fourth wiring layer of the embodiment in comparison with the modification.

FIG. 28 is a perspective view illustrating a head-mounted display using an electro-optical device.

FIG. 29 is a diagram illustrating an optical configuration of the head-mounted display.

### DESCRIPTION OF EXEMPLARY EMBODIMENTS

An electro-optical device according to an embodiment of the present disclosure will be described below with reference to the accompanying drawings. In each of the drawings, dimensions and scale of each part are appropriately different from actual ones. Moreover, the embodiment described below is a suitable specific example, and various technically preferable limitations are applied, but the scope of the disclosure is not limited to these modes unless they are specifically described in the following description as limiting the disclosure.

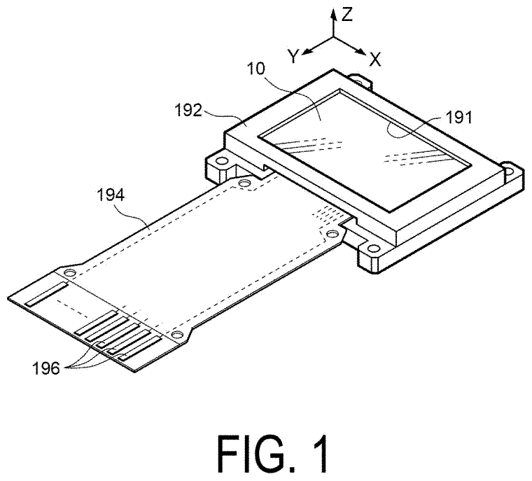

FIG. 1 is a perspective view illustrating an electro-optical device 10. The electro-optical device 10 is a micro display panel that displays an image, for example, in a head-mounted display (HMD) or the like. The electro-optical device 10 includes a plurality of pixel circuits, a drive circuit that drives the pixel circuits, and the like. The pixel circuits and the drive circuit are integrated into a semiconductor substrate. The semiconductor substrate is typically a silicon substrate, but may be a different semiconductor substrate.

As illustrated in the figure, the electro-optical device 10 is housed in a frame shaped case 192 including an opening 191. One end of a flexible printed circuit (FPC) substrate 194 is coupled to the electro-optical device 10. The FPC substrate 194 has the other end provided with a plurality of terminals 196. The plurality of terminals 196 are coupled to a host apparatus that is not illustrated. The host apparatus supplies video data to the electro-optical device 10. The video data is data representing an image to be displayed by the electro-optical device 10.

In the drawings, an X direction is a lateral direction of the display image on the electro-optical device 10, and a Y direction is a vertical direction of the display image. A two-dimensional plane defined in the X direction and the Y direction is a substrate surface of the semiconductor substrate. A Z direction is perpendicular to the X direction and the Y direction and is an emission direction of light emitted from light-emitting elements described below.

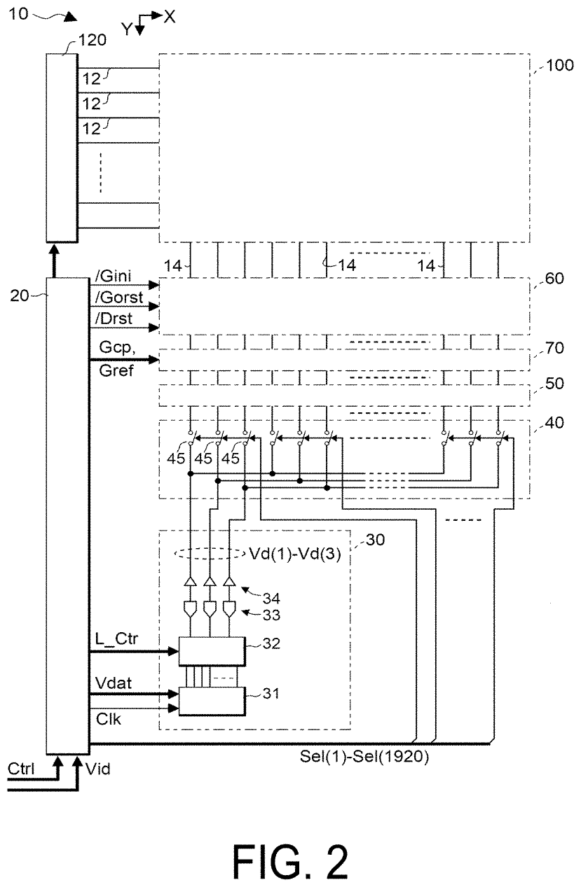

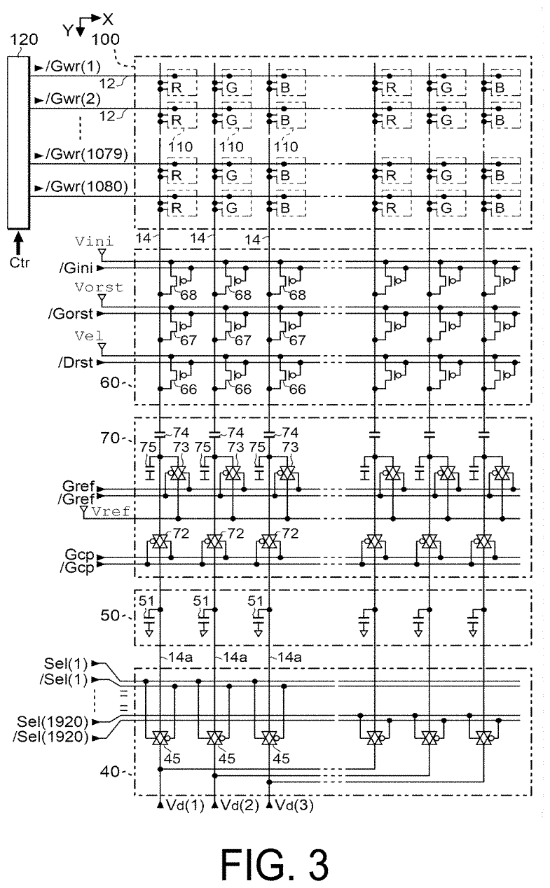

FIG. 2 is a block diagram illustrating an electrical configuration of the electro-optical device 10. FIG. 3 is a diagram illustrating a configuration of a main part of the electro-optical device 10.

As illustrated in FIG. 2, the electro-optical device 10 includes a control circuit 20, a data signal output circuit 30, a switch group 40, a capacitive element group 50, an initialization circuit 60, an auxiliary circuit 70, a display region 100, and a scanning line drive circuit 120.

As illustrated in FIG. 3, in the electro-optical device 10, for example, 1080 rows of scanning lines 12 are provided to extend in the X direction in the figure, and 5760 (=1920×3) columns of data lines 14 are provided to extend in the Y direction while being electrically insulated from the scanning lines 12.

The rows of the scanning lines 12 are distinguished from each other by being referred to as the first, second, third, . . . 1079th, and 1080th rows in order from the upper side in the figure. For general description on the scanning line 12 without specifying the row, the term i-th row may be used, where i is an integer that is 1 or more and 1080 or less. The columns of the data lines 14 are distinguished from each other by being referred to as the first, second, third, . . . , 5758th, 5759th, and 5760th columns in order from the left in the figure. Every three columns of the data lines 14 are grouped. For general description on the groups, a total of three columns of the data lines 14, that is, the (3j−2)th, (3j−1)th, and (3j)th columns belong to the j-th group as counted from the left, where j is an integer that is 1 or more and 1920 or less.

Pixel circuits 110R, 110G, and 110B are provided corresponding to the scanning line 12 arrayed in the 1080th row and the data line 14 arrayed in the 5760th column. More specifically, the pixel circuit 11CR is provided corresponding to an intersection between the scanning line 12 in the i-th row and the data line 14 in the (3j−2)th column. The pixel circuit 110G is provided corresponding to an intersection between the scanning line 12 in the i-th row and the data line 14 in the (3j−1)th column. The pixel circuit 110B is provided corresponding to an intersection between the scanning line 12 in the i-th row and the data line 14 in the (3j)th column.

The pixel circuit 11CR includes a light-emitting element light emitted from which includes a red component. The pixel circuit 110G includes a light-emitting element light emitted from which includes a green component. The pixel circuit 110B includes a light-emitting element light emitted from which includes a blue component. One color is expressed through additive color mixing of light emitted from the pixel circuits 110R, 110B, and 110G adjacent to each other in the same row. Thus, in the present embodiment, an image is displayed in which pixels expressing colors are arrayed in a matrix with 1080 lines in a vertical direction×1920 columns in a lateral direction.

The pixel circuits 110R, 110G, and 110B express the red component, the green component, and the blue component of one pixel of color in this order, and thus are supposed to be referred to as sub pixel circuits in a strict sense, but are referred to as the pixel circuits in the description for the sake of convenience.

In the embodiment, the array (1080 rows×1920 columns) of color pixels expressed by the pixel circuits 110R, 110G, and 110B matches the array of color pixels in an image to be displayed.

Note that the array of color pixels expressed by the pixel circuits 110R, 110G, and 110B does not necessarily match the array of color pixels in the image to be displayed.

When the pixel circuits 110R, 110G, and 110B are generally described with their colors not specified, the pixel circuits are described while being denoted simply by reference numeral 110. A region in which the pixel circuits 110R, 110G, and 110B are arrayed is an example of the display region 100.

The expression of an object “extending in the X direction or the Y direction” is used to mean a state where the object is provided over a plurality of pixel circuits 110 along the column or row direction, rather than being within a single pixel circuit 110.

In FIG. 2, the control circuit 20 controls each unit based on video data Vid and a control signal Ctrl supplied from the host apparatus.

The video data Vid is supplied in synchronization with a synchronization signal, and designates the gradation level of the pixels in the image to be displayed by the electro-optical device 10, with eight bits for each of red, green, and blue, for example. The synchronization signal includes a vertical synchronization signal that instructs a start of vertical scanning of the video data Vid, a horizontal synchronization signal that instructs a start of horizontal scanning, and a dot clock signal that indicates a timing of one pixel of the video data Vid.

The control circuit 20 generates, as logical signals, control signals Gref, Gcp, /Drst, /Gorst, /Gini, L_Ctr, and Sel (1) to Sel (1920) as well as a clock signal Clk to control each unit. Additionally, the control circuit 20 controls the scanning line drive circuit 120 based on the vertical synchronization signal included in the control signal Ctrl.

Although not elaborated in in FIG. 2, the control circuit 20 outputs a control signal /Gcp in logically inverted relationship with the control signal Gcp, a control signal /Gref in logically inverted relationship with the control signal Gref, and control signals /Sel (1) to /Sel (1920) in logically inverted relationship with Sel (1) to Sel (1920).

An L level and an H level of these logical signals are respectively 0 V that is the reference for the zero voltage, and 6.0 V, for example. Control signals /Gel (1) to /Gel (1080) described below have an M level in addition to the L level and the H level, to have three levels. The M level is a level with a value between the L level and the H level, which is 4 to 5 V, for example.

The scanning line drive circuit 120 is a circuit that drives the pixel circuits 110R, 110G, and 110B arrayed in 1920 rows and 5760 columns on a row-by-row basis, and outputs a scanning signal as well as various control signals synchronized with the scanning signal although omitted in FIG. 3.

The data signal output circuit 30 outputs a data signal to the data lines 14. Specifically, the data signal output circuit 30 outputs the data signal indicating voltage corresponding to the gradation level of each pixel. In the present embodiment, the data signal output circuit 30 outputs the data signal to be supplied to the data lines 14, with a voltage amplitude of the data signal compressed. Thus, the compressed data signal also indicates voltage corresponding to the gradation level of the pixel.

The data signal output circuit 30 also has a function of performing parallel conversion on video data Vdat serially supplied into a plurality of phases (“3” phases corresponding to the number of columns of the data lines 14 forming a group in this example), and outputting the resultant data. For simplicity, it is described hereinafter as “3” phases.

The data signal output circuit 30 includes a shift register 31, a latch circuit 32, a D/A conversion circuit group 33, and an amplifier group 34.

The shift register 31 sequentially transfers the video data Vdat serially supplied in synchronization with the clock signal Clk, and stores the video data Vdat corresponding to a single row, that is, 5760 pieces of the video data Vdat corresponding to the number of pixel circuits 110. In the present embodiment, the parallel conversion of the video data Vdat into three phases is performed, and then the resultant data is output. Thus, the shift register 31 sequentially stores the video data Vdat for three phases (three pixels) at a time.

The latch circuit 32 latches the video data Vdat stored for three phases at a time in the shift register 31 in accordance with the control signal L_Ctr, and performs parallel conversion for output on the latched video data Vdat into three phases in accordance with the control signal L_Ctr.

The D/A conversion circuit group 33 includes three digital to analog (D/A) converters. The three D/A converters convert the three-phase video data Vdat output from the latch circuit 32, into an analog signal.

The amplifier group 34 includes three amplifiers. The three amplifiers amplify the three-phase analog signal output from the D/A conversion circuit group 33, and outputs resultant data signals Vd(1), Vd(2), and Vd(3).

An example of a configuration of the D/A conversion circuit may include a configuration in which a switch and a capacitive element are provided corresponding to each bit, and the switch controls charging and discharging of the capacitive element in accordance with whether each bit is “0” or “1”. Depending on the configuration of the data signal output circuit 30, the amplifier group 34 is not necessarily provided. For example, with the configuration in which a switch and a capacitive element are provided corresponding to each bit, and the switch controls charging and discharging of the capacitive element in accordance with each bit, employed as the configuration of the D/A conversion circuit, the amplifier group 34 is not necessarily provided.

During a compensation period before a writing period, the control circuit 20 sequentially outputs the control signals Sel (1) to Sel (1920) that exclusively rise to the H level, as described below.

In FIG. 3, the scanning line drive circuit 120 supplies scanning signals /Gwr(1), /Gwr(2), . . . , /Gwr(1079), and /Gwr(1080) to the scanning lines 12 of the first, second, third, . . . , 1079th, and 1080th rows in this order.

The electro-optical device 10 is provided with data transfer lines 14a corresponding one to one to the data lines 14.

The switch group 40 is a collection of transmission gates 45 provided for the respective data transfer lines 14a. Of the transmission gates 45, 1920 transmission gates 45 corresponding to the data transfer lines 14a of the first, fourth, seventh, . . . , and 5758th columns have input terminals commonly coupled. The input terminals are supplied with the data signal Vd (1) in time series for each pixel.

Of the transmission gates 45, 1920 transmission gates 45 corresponding to the data transfer lines 14a of the second, fifth, eighth, . . . , and 5759th columns have input terminals commonly coupled and supplied with the data signal Vd(2) in time series for each pixel.

Similarly, of the transmission gates 45, 1920 transmission gates 45 corresponding to the data transfer lines 14a of the third, sixth, ninth, . . . , and 5760th columns have input terminals commonly coupled and supplied with the data signal Vd(3) in time series for each pixel.

The transmission gate 45 of one column has an output terminal coupled to one end of the data transfer lines 14a of the column.

The three transmission gates 45 corresponding to the (3j−2)th, (3j−1)th, and (3j)th columns belonging to the j-th group are in an ON state between the input terminal and the output terminal when the control signal Sel(j) is at the H level (when the control signal /Sel(j) is at the L level).

Note that in FIG. 3, only the first group and the 1920th group are illustrated, and the other groups are omitted due to limitation in space of the paper sheet. The transmission gates 45 in FIG. 3 are simply illustrated as a simple switch in FIG. 2.

In this description, the “ON state” of the switch, transistor, or transmission gate is a state in which the electrical coupling is established between both ends of the switch, a source node and a drain node of the transistor, or both ends of the transmission gate, resulting in a low impedance state. The “OFF state” of the switch, transistor, or transmission gate is a state in which the electrical coupling is released between both ends of the switch, a source node and a drain node of the transistor, or both ends of the transmission gate, resulting in a high impedance state.

Also, in the description, “electrically coupled” or simply “coupled” means a state in which two or more elements are directly or indirectly coupled or connected.

The capacitive element group 50 is a collection of capacitive elements 51 provided for the respective data transfer lines 14a. One end of a capacitive element 41 corresponding to the data transfer line 14a of one column is coupled to one end of the data transfer line 14a. The capacitive element 41 has the other end grounded to a constant potential, that is, the potential that is the reference for the zero voltage, for example.

The auxiliary circuit 70 is a collection of transmission gates 72 and 73 provided for each column and capacitive elements 74 and 75 provided for each column.

The transmission gate 72 corresponding to one column is in the ON state between the input terminal and the output terminal when the control signal Gcp is at the H level (when the control signal /Gcp is at the L level). The input terminal of the transmission gate 72 corresponding to one column is coupled to the other end of the data transfer line 14a of the column. The output terminal of the transmission gate 72 corresponding to the column is coupled to the output terminal of the transmission gate 73 corresponding to the column, one end of the capacitive element 74 corresponding to the column, and one end of the capacitive element 75 corresponding to the column.

The transmission gate 73 corresponding to one column is in the ON state between the input terminal and the output terminal when the control signal Gref is at the H level (when the control signal /Gref is at the L level). A voltage Vref is applied to the input terminal of the transmission gate 73 corresponding to one column.

The other end of the capacitive element 75 corresponding to one column is grounded to a constant potential, that is, the potential to be the reference for the zero voltage, for example.

The other end of the capacitive element 74 corresponding to one column is coupled to one end of the data line 14 correspond to the column.

The initialization circuit 60 is a collection of P-channel MOS type transistors 66 and 68 and an N-channel MOS type transistor 67 provided for each data line 14.

The control signal /Drst is supplied to a gate electrode of the transistor 66 corresponding to the data line 14 of one column. A voltage Vel is applied to the source node of the transistor 66. The drain node of the transistor 66 is coupled to the data line 14 of the column.

The control signal /Gorst is supplied to a gate electrode of the transistor 67 corresponding to the data line 14 of one column. A voltage Vorst is applied to the source node of the transistor 67. The drain node of the transistor 67 is coupled to the data line 14 of the column. The control signal /Gini is supplied to a gate electrode of the transistor 68 corresponding to the data line 14 of one column. A voltage Vini is applied to the source node of the transistor 68. The drain node of the transistor 68 is coupled to the data line 14 of the column.

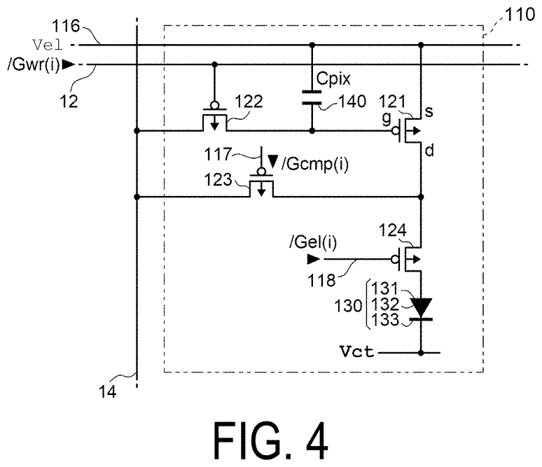

FIG. 4 is a diagram illustrating a configuration of the pixel circuit 110. The pixel circuits 110R, 110G, and 110B arrayed in 1080 rows and 5760 columns have the same configuration from the electrical point of view. Therefore, the pixel circuit 110 will be described with one pixel circuit 110 corresponding to the i-th row and the (3j−2)th column as a representative.

As illustrated in the drawing, the pixel circuit 110 includes P-channel MOS type transistors 121 to 124, an OLED 130, and a capacitive element 140.

A scanning signal /Gwr(i) and control signals /Gcmp(i) and/Gel(i) are supplied from the scanning line drive circuit 120 to the pixel circuit 110 in the i-th row.

The OLED 130 is an example of a light-emitting element in which a light-emitting layer 132 is sandwiched between a pixel electrode 131 and a common electrode 133. The pixel electrode 131 functions as an anode, and the common electrode 133 functions as a cathode. The common electrode 133 may have light reflectivity and light transmissive properties. When a current flows from the anode to the cathode of the OLED 130, holes injected from the anode and electrons injected from the cathode are recombined in the light-emitting layer 132 to generate excitons and generate white light.

In the case of the color display as in the present embodiment, the generated white light resonates in an optical resonator configured of a reflective layer omitted in the figure and a semi-reflective and semi-transmissive layer, for example, and is emitted at a resonance wavelength set corresponding to any of red (R), green (G), and blue (B). A color filter corresponding to the color is provided on the emission side of the light from the optical resonator as described below. Thus, the emitted light from the OLED 130 is visually recognized by an observer through coloration by the optical resonator and the color filter.

Note that when the electro-optical device 10 displays only a single color image based only on brightness and darkness, the color filter described above is omitted.

In the transistor 121 of the pixel circuit 110 in the i-th row and the (3j−2)th column, a gate electrode g is coupled to the drain node of the transistor 122 and one end of the capacitive element 140, a source node s is coupled to a wire 116 for the voltage Vel, and a drain node d is coupled to a source node of the transistor 123 and a source node of the transistor 124.

The capacitive element 140 has the other end coupled to a constant voltage, that is the wire 116 for the voltage Vel, for example. Thus, the capacitive element 140 maintains the voltage between the gate electrode g and the source node s of the transistor 121.

The capacitive element 140 is formed by sandwiching an insulating film by electrodes made of wiring layers different from each other in the semiconductor substrate as described below. Alternatively, capacitance parasitic to the gate electrode g of the transistor 121 may be used.

In the transistor 122 of the pixel circuit 110 in the i-th row and the (3j−2)th column, a gate electrode is coupled to the scanning line 12 in the i-th row, and a source node is coupled to the data line 14 in the (3j−2)th column.

In the transistor 123 of the pixel circuit 110 in the i-th row and the (3j−2)th column, a gate electrode is supplied with the control signal /Gcmp(i), and a drain node is coupled to the data line 14 in the (3j−2)th column. The control signal /Gcmp(i) is supplied from the scanning line drive circuit 120 through a control line 117 in the i-th row.

In the transistor 124 of the pixel circuit 110 in the i-th row and the (3j−2)th column, a gate electrode is supplied with the control signal /Gel(i), and a drain node is coupled to the pixel electrode 131 that is the anode of the OLED 130. The control signal /Gel(i) is supplied from the scanning line drive circuit 120 through a control line 118 in the i-th row.

The common electrode 133 functioning as the cathode of the OLED 130 is coupled to a feed line of a voltage Vct. Since the electro-optical device 10 is formed on the semiconductor substrate, a substrate potential of the P-channel transistors 121 to 124 is set to the voltage Vel, for example.

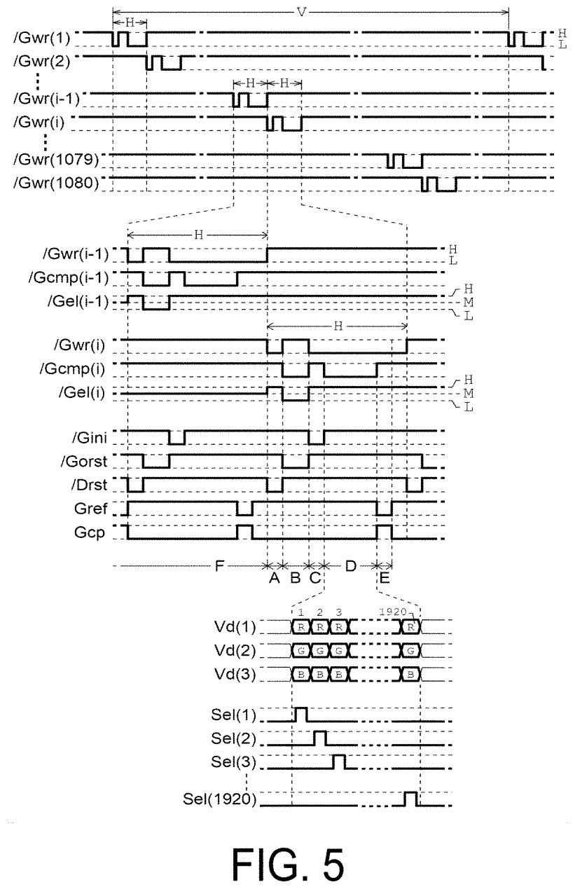

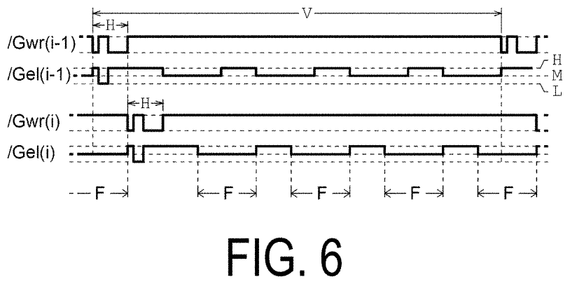

FIG. 5 is a timing chart illustrating an operation of the electro-optical device 10. FIG. 6 is a diagram illustrating an example of relationship between a scanning signal and a control signal for light emission.

In the electro-optical device 10, horizontal scanning is performed one by one in the order of the first, second, third, . . . , and m-th rows during a period of a single frame (V).

In the present description, the period of a single frame (V) refers to a period required for displaying one frame of an image designated by the video data Vid. When a length of the period of a single frame is the same as a vertical synchronization period, for example, when a frequency of a vertical synchronization signal included in a synchronization signal Sync is 60 Hz, it is 16.7 milliseconds, which corresponds to one cycle of the vertical synchronization signal. A period of time required for the horizontal scanning for a single row is defined as a horizontal scanning period (H). Note that in FIGS. 5 and 6, the vertical scale indicating the voltage does not necessarily conform to the signals.

The operation of the pixel circuits 110 for each row is substantially the same in the horizontal scanning period (H). Furthermore, the operation of the pixel circuits 110 in the first to 5760th columns and in the row scanned in the horizontal scanning period (H) is substantially the same. Therefore, the following description focuses on the pixel circuit 110 in the i-th row and the (3j−2)th column.

In the electro-optical device 10, the horizontal scanning period (H) is divided into five periods that are initialization periods (A), (B), and (C), a compensation period (D), and a writing period (E) in order of time. Furthermore, as the operation of the pixel circuits 110, a light emission period (F) is further provided in addition to the five periods described above. The light emission period (F) in the i-th row is a period in which the control signal /Gel(i) is at the M level as illustrated in FIG. 6.

Of the initialization periods (A), (B), and (C), the initialization period (A) is a period for setting the transistor 121 to the OFF state, and is a period for pre-preparation processing for the initialization period (C). The initialization period (B) is a period for resetting the potential at the anode of the OLED 130. The initialization period (C) is a period for applying voltage for turning ON the transistor 121 to the gate electrode g of the transistor 121 at the beginning of the compensation period (E).

In the initialization period (A) of the horizontal scanning period (H), the control signal /Gini is at the H level, the control signal /Gorst is at the H level, the control signal /Drst is at the L level, the control signal Gref is at the H level, and the control signal Gcp is at the L level. Thus, the transistor 68 is in the OFF state, the transistor 67 is in the OFF state, the transistor 66 is in the ON state, the transmission gate 73 is in the ON state, and the transmission gate 72 is in the OFF state.

In the initialization period (A) of the horizontal scanning period (H) in which the i-th row is selected, the scanning signal /Gwr(i) is at the L level, the control signal /Gcmp(i) is at the H level, and the control signal /Gel(i) is at the H level. Thus, in this pixel circuit 110, the transistor 122 is in the ON state, and the transistors 123 and 124 are in the OFF state.

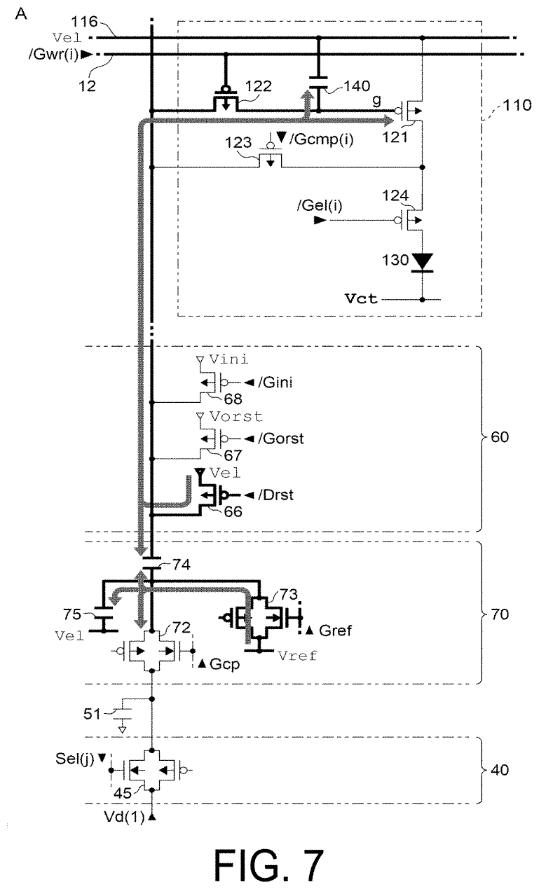

Thus, in the initialization period (A), as illustrated in FIG. 7, the voltage Vref is applied to one end of the capacitive element 74, one end of the capacitive element 75, and the output terminal of the transmission gate 72, through the transmission gate 73. In the pixel circuits 110, the voltage Vel is applied to one end of the capacitive element 140 and the gate electrode g of the transistor 121 through the transistor 66, the data line 14, and the transistor 122 in this order. The voltage Vel applied to the gate electrode g results in zero voltage between the gate electrode g and the source node s. Thus, the transistor 121 forcibly transitions to the OFF state, and the current flowing in the OLED 130 is interrupted. The voltage Vel is applied to the other end of the capacitive element 74 through the data line 14, whereby the capacitive element 74 is charged to voltage |Vel−Vref|.

In the initialization period (B) of the horizontal scanning period (H), the control signal /Gini is at the H level, the control signal /Gorst is at the L level, the control signal /Drst is at the H level, the control signal Gref is at the H level, and the control signal Gcp is at the L level. Thus, the transistor 68 stays in the OFF state, the transistor 67 transitions to the ON state, the transistor 66 transitions to the OFF state, the transmission gate 73 stays in the ON state, and the transmission gate 72 stays in the OFF state.

In the initialization period (B) of the horizontal scanning period (H) in which the i-th row is selected, the scanning signal /Gwr(i) is at the H level, the control signal /Gcmp(i) is at the L level, and the control signal /Gel(i) is at the L level. Thus, in this pixel circuit 110, the transistor 122 is in the OFF state, and the transistors 123 and 124 are in the ON state.

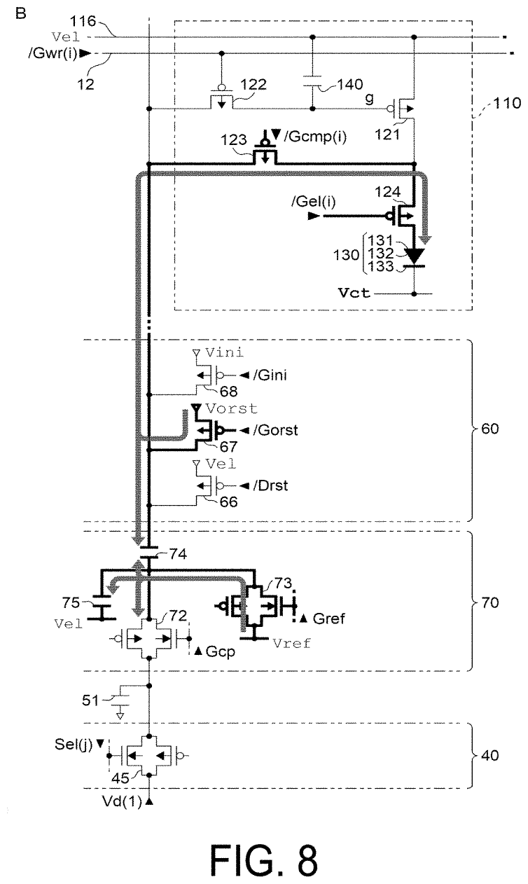

Thus, in the initialization period (B), one end of the capacitive element 74, one end of the capacitive element 75, and the output terminal of the transmission gate 72 are maintained at the voltage Vref as illustrated in FIG. 8. In the pixel circuits 110, the voltage Vorst is applied to the pixel electrode 131 that is the anode of the OLED 130, through the transistor 67, the data line 14, and the transistors 123 and 124 In the OLED 130, the light-emitting layer 132 is sandwiched by the pixel electrode 131 and the common electrode 133, thus there is a parasitic capacitance component. In the initialization period (B), the voltage held in the capacitance component as a result of the application of the voltage Vorst to the pixel electrode 131, more specifically, the voltage corresponding to the current flowing in the OLED 130 in the light emission period (F) is reset. The voltage Vorst is voltage for turning OFF the light emission by the OLED 130, and specifically is zero voltage corresponding to the L level or voltage (0 to 1 V) close to the zero voltage. The voltage Vorst is applied to the other end of the capacitive element 74 through the data line 14, whereby the capacitive element 74 is charged to voltage |Vorst−Vref|.

In the initialization period (C) of the horizontal scanning period (H), the control signal /Gini is at the L level, the control signal /Gorst is at the H level, the control signal /Drst is at the H level, the control signal Gref is at the H level, and the control signal Gcp is at the L level. Thus, the transistor 68 transitions to the ON state, the transistor 67 transitions to the OFF state, the transistor 66 stays in the OFF state, the transmission gate 73 stays in the ON state, and the transmission gate 72 stays in the OFF state.

In the initialization period (C) of the horizontal scanning period (H) in which the i-th row is selected, the scanning signal /Gwr(i) is at the L level, the control signal /Gcmp(i) is at the H level, and the control signal /Gel(i) is at the H level. Thus, in this pixel circuit 110, the transistor 122 is in the ON state, and the transistors 123 and 124 are in the OFF state.

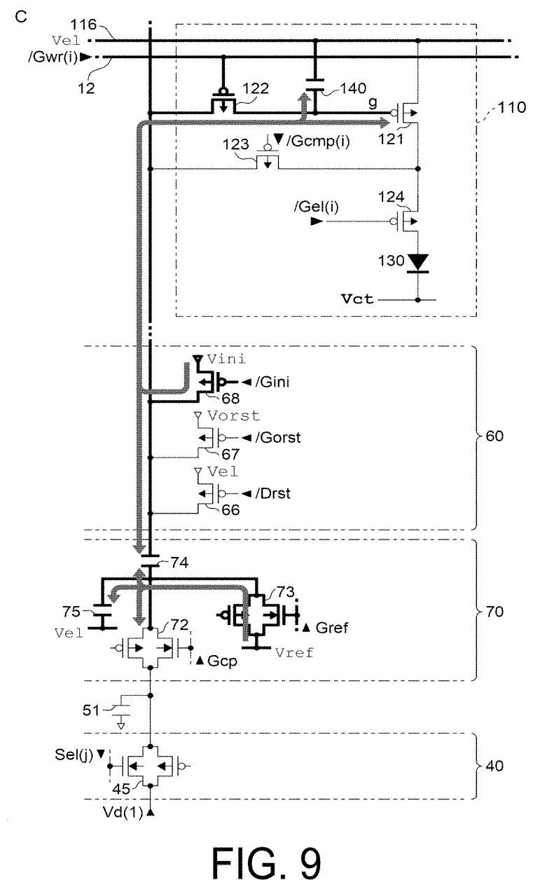

Thus, in the initialization period (C), one end of the capacitive element 74, one end of the capacitive element 75, and the output terminal of the transmission gate 72 are maintained at the voltage Vref as illustrated in FIG. 9. In the pixel circuits 110, the voltage Vini is applied to one end of the capacitive element 140 and the gate electrode g of the transistor 121 through the transistor 68, the data line 14, and the transistor 122 in this order. The voltage Vini is applied to the other end of the capacitive element 74 through the data line 14, whereby the capacitive element 74 is charged to voltage |Vini−Vref|.

In the compensation period (D) of the horizontal scanning period (H), the control signal /Gini is at the H level, the control signal /Gorst is at the H level, the control signal /Drst is at the H level, the control signal Gref is at the H level, and the control signal Gcp is at the L level. Thus, the transistor 68 transitions to the OFF state, the transistor 67 stays in the OFF state, the transistor 66 stays in the OFF state, the transmission gate 73 stays in the ON state, and the transmission gate 72 stays in the OFF state.

In the compensation period (D) of the horizontal scanning period (H) in which the i-th row is selected, the scanning signal /Gwr(i) stays at the L level, the control signal /Gcmp(i) transitions to the L level, and the control signal /Gel(i) stays at the H level. Thus, in this pixel circuit 110, the transistor 122 stays in the ON state, and the transistor 123 is in the ON state, and the transistor 124 is in the OFF state.

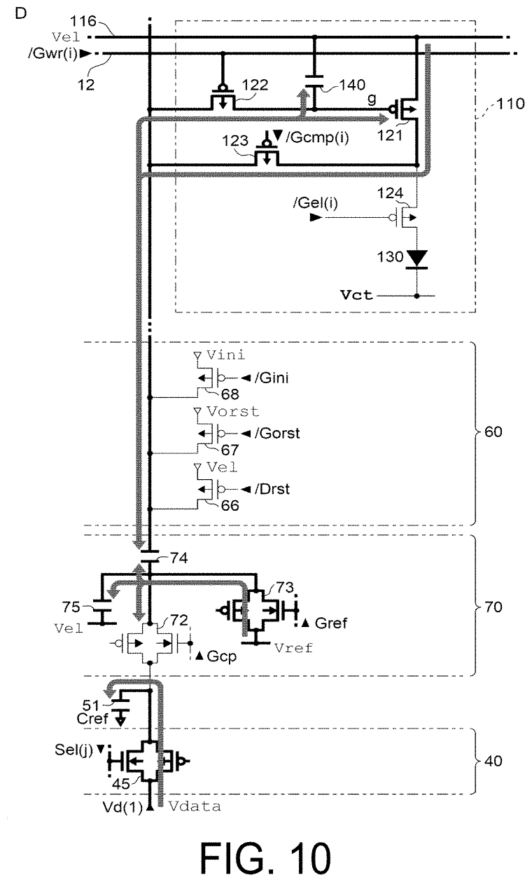

Thus, in the compensation period (D), one end of the capacitive element 74, one end of the capacitive element 75, and the output terminal of the transmission gate 72 are maintained at the voltage Vref as illustrated in FIG. 10.

In the pixel circuits 110, one end of the capacitive element 140 is maintained at the voltage Vini in the preceding initialization period (C). Thus, the voltage between the gate electrode g and the source node s of the transistor 121 is maintained at (Vel−Vini).

In this state, when the transistor 123 transitions to the ON state, the transistor 121 is in a diode coupled state, that is, a state where the gate electrode and the drain node are coupled. Thus, a voltage Vgs between the gate electrode g and the source node s of the transistor 121 converges toward a threshold voltage of the transistor 121. Here, this threshold voltage is denoted by Vth for the sake of convenience, the voltage at the gate electrode g of the transistor 121 converges to a voltage (Vel−Vth) corresponding to threshold voltage Vth.

At the beginning of the compensation period (D), current needs to flow from the source node to the drain node in the transistor 121 in the diode coupled state. Thus, the voltage Vini applied to the gate electrode g in the initialization period (C) before the compensation period (D) satisfies the relationship Vini<Vel−Vth.

In the compensation period (D), the gate electrode g of the transistor 121 is coupled to the data line 14 via the transistor 122, and the drain node d of the transistor 121 is coupled to the data line 14 via the transistor 123. Thus, the voltage also at this data line 14 and the other end of the capacitive element 74 converges toward the voltage (Vel−Vth). Therefore, the capacitive element 74 is charged to substantially a |voltage Vel−Vth−Vref|.

On the other hand, in the compensation period (D), the control signals Sel (1) to Sel (1920) sequentially and exclusively rise to the H level. Although not elaborated in FIG. 5, in the compensation period (D), the control signals /Sel (1) to /Sel (1920) sequentially and exclusively drop to the L level in synchronization with the control signals Sel (1) to Sel (1920).

When the control signal Sel (j) among the control signals Sel (1) to Sel (1920) rises to the H level for example, the data signal output circuit 30 outputs the data signals Vd (1) to Vd (3) corresponding to the RGB components of the color pixels corresponding to the intersection between the scanning line 12 in the i-th row and the data lines 14 belonging to the j-th group.

More specifically, in a period where the control signal Sel (j) is at the H level, the data signal output circuit 30 outputs the data signals Vd (1), Vd (2), and Vd (3) respectively as the R component, the G component, and the B component of the color pixel in the i-th row and the j-th column.

When the control signals Sel (1) to Sel (1920) sequentially and exclusively rise to the H level, the voltages of the data signals corresponding to the respective pixels are held by the capacitive elements 51 corresponding to the first to 5760th columns.

FIG. 10 illustrates a state where the control signal Sel(j) corresponding to the j-th group to which the pixel circuit 110 belongs rises to the H level in the compensation period (D), voltage Vdata of the data signal Vd (1) is held by the capacitive element 51.

In the writing period (E) of the horizontal scanning period (H), the control signal /Gini is at the H level, the control signal /Gorst is at the H level, the control signal /Drst is at the H level, the control signal Gref is at the L level, and the control signal Gcp is at the H level. Thus, the transistors 68, 67, and 66 stay in the OFF state, the transmission gate 73 transitions to the OFF state, and the transmission gate 72 transitions to the ON state. In the writing period (E) of the horizontal scanning period (H) in which the i-th row is selected, the scanning signal /Gwr(i) stays at the L level, the control signal /Gcmp(i) transitions to the H level, and the control signal /Gel(i) stays at the H level. Thus, in this pixel circuit 110, the transistor 122 is in the ON state, and the transistors 123 and 124 are in the OFF state.

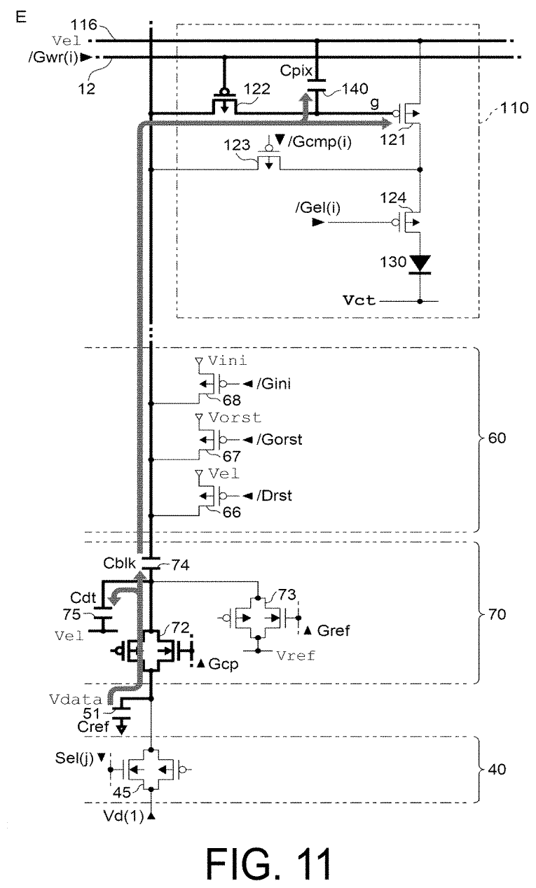

Thus, in the writing period (E) of the horizontal scanning period (H) in which the i-th row is selected, as illustrated in FIG. 11, one end of the capacitive element 74 changes from the voltage Vref in accordance with the voltage held by the capacitive element 51, due to the transmission gate 73 being in the OFF state and the transmission gate 72 being in the ON state. The change in voltage propagates to the gate electrode g via the data lines 14 and the transistor 122 in this order through the capacitive element 74. The voltage at the gate electrode g after the change is held by the capacitive element 140.

As illustrated in FIG. 11, the capacity size of the capacitive element 51 is denoted by Cref, the capacity size of the capacitive element 74 is denoted by Cblk, and the capacity size of the capacitive element 75 is denoted by Cdt, and the capacity size of the capacitive element 140 is denoted by Cpix. The voltage of the data signal Vd (1) held by the capacitive element 51 in the compensation period (D) is denoted by Vdata.

A voltage change value ΔV at the gate electrode g from the compensation period (D) to the writing period (E) is expressed by the following Formula (1)

$$\begin{matrix}[ Mathematical Equation 1 ] & \\ \begin{matrix}Δ V = \frac{\frac{Cblk ( Cdt + Cpix )}{Cblk + Cdt + Cpix} \times Vref + Cref \times Vdata}{\frac{Cblk ( Cdt + Cpix )}{Cblk + Cdt + Cpix} \times ( Vdata - Vref )} - Vref \\ = \frac{Cref}{\frac{Cblk ( Cdt + Cpix )}{Cblk + Cdt + Cpix}} \times ( Vdata - Vref ) \\ = Ka \times ( Vdata - Vref )\end{matrix} & ( 1 )\end{matrix}$$

Thus, as can be seen in Formula (1), a value of the gate electrode g changes to that obtained by multiplying the value of change in voltage (Vdata−Vref) at one end of the capacitive element 74 by a coefficient Ka. Note that the coefficient Ka is smaller than “1”, and is determined based on the capacity sizes Cref, Cblk, Cdt, and Cpix. In other words, the coefficient Ka is set to be less than “1” with the capacity sizes Cref, Cblk, Cdt, and Cpix designed to be appropriate values. When the coefficient Ka is less than “1”, the voltage amplitude from the minimum value to the maximum value of the voltage Vdata of the data signal is compressed in accordance with the coefficient Ka, and the resultant voltage propagates to the gate electrode g.

When the pixel circuits 110 are miniaturized, the current flowing in the OLED 130 may change sharply in response to a slight change in the voltage Vgs between the gate electrode g and the source node s in the transistor 121.

Even in this case, since the voltage Vdata of the data signal propagates to the gate electrode g after having the voltage amplitude compressed in accordance with the coefficient Ka in the present embodiment, whereby current flowing in the OLED 130 can be accurately controlled.

The light emission period (F) comes after the writing period (E). In the present embodiment, there are four light emission periods (F) for the i-th row as illustrated in FIG. 6 for example, from the horizontal scanning period (H) in which the i-th row is selected to the horizontal scanning period (H) in which the i-th row is selected again after the period of a single frame (V) elapses. Specifically, the horizontal scanning period (H) in which the i-th row is selected is followed by the four light emission periods (F) in which the control signal /Gel (i) is at the M level at a substantially equal interval, with the duration of the M level time period being set to be substantially the same thereamong.

The light emission period (F) for the i-th row may continue, that is, the control signal /Gel(i) may be maintained at the M level, from the horizontal scanning period (H) in which the i-th row is selected to the horizontal scanning period (H) in which the i-th row is selected again after the period of a single frame (V) elapses.

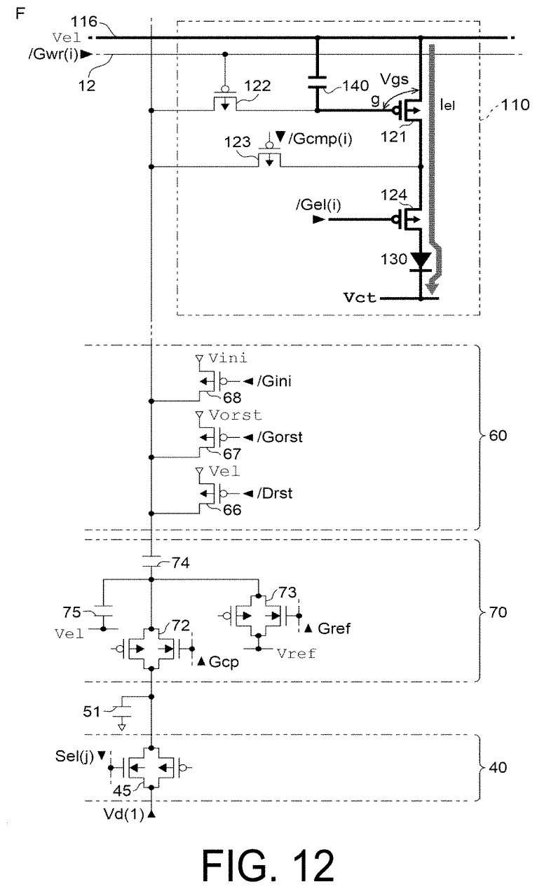

When the control signal /Gel(i) is at the M level in the light emission period (F), as illustrated in FIG. 12, the transistor 121 makes current Iel that corresponds to the voltage Vgs and is limited by a resistance between the source node and the drain node of the transistor 124 flow in the OLED 130. Thus, the OLED 130 emits light with luminance corresponding to the current Iel.

Note that in FIGS. 7 to 12, regions where the capacitive element group 50 and the initialization circuit 60 are provided are not particularly distinguished from one another.

In the present embodiment, the amplitude of the voltage Vdata of the data signal output from the data signal output circuit 30 is compressed through the capacitive element 74, to be supplied as the data signal to the gate electrode g of the pixel circuit 110.

On the other hand, in the compensation period (D), compensation is performed for the threshold voltage Vth and the transistor 121.

Then, the effectiveness of the compensation period (D) will be described next. To prevent the formula from being complicated in the description on the effectiveness, it is assumed that the compression ratio of the voltage Vdata of the data signal is “1”, that is, it is assumed that the voltage Vdata of the data signal is directly supplied to the data line 14 in the writing period (E) after the compensation period (D). Furthermore, it is assumed that in the light emission period (F), the voltage at the L level and not the M level is applied to the gate electrode of the transistor 124, to turn ON the transistor 124, and the resistance between the source node and the drain node is ideally zero.

First of all, the current Iel flowing in the OLED 130 in the light emission period (F) can be expressed as in the following Formula (2).

[Mathematical Equation 2]

Iel=k₁(Vgs−Vth)² (2)

Note that the coefficient k1 in Formula (2) is expressed by the following Formula (3).

[Mathematical Equation 3]

k₁=(W/2L)·μCox (3)

In Formula (3), W represents the channel width of the transistor 121, L represents the channel length of the transistor 121, p represents the mobility of the carrier, and Cox represents the capacity per unit area of the (gate) oxide film in the transistor 121.

In a configuration where the voltage Vdata of the data signal is not compressed and the threshold voltage of the transistor 121 is not compensated, the voltage Vgs between the gate electrode g and the source node s of the transistor 121 when the voltage Vdata of the data signal is directly applied to the gate electrode g of the transistor 121 can be expressed as in the following Formula (4).

[Mathematical Equation 4]

Vgs=|Vel−Vdata| (4)

The resultant current Iel flowing in the OLED 130 can be expressed as in the following Formula (5).

$$\begin{matrix}[ Mathematical Equation 5 ] & \\ \begin{matrix}Iel = {{k}_{1} ( Vgs - Vth )}^{2} \\ = {{k}_{1} ( Vel - Vdata - Vth )}^{2}\end{matrix} & ( 5 )\end{matrix}$$

As can be seen in Formula (5), the current Iel is affected by the threshold voltage Vth. The threshold voltage Vth of the transistor 121 fluctuates in a range of several mV to several tens of mV, in relation to the semiconductor process. When the threshold voltage Vth of the transistor 121 fluctuates in a range of several mV to several tens of mV, there may be a difference as large as 40% in the current Iel between the adjacent pixel circuits 110.

The current and luminance characteristics in the OLED 130 are in a substantially linear relationship. Thus, with the configuration where the threshold voltage Vth is not compensated, even when data signals of the same voltage Vdata are supplied to the two pixel circuits 110 to make the two corresponding OLEDs 130 emit light with the same luminance, different currents actually flow in the OLEDs 130. Thus, with the configuration where the threshold voltage Vth is not compensated, the luminance varies to largely compromise the display quality.

The following Formula (6) expresses the voltage Vgs between the gate electrode g and the source node s of the transistor 121 when the voltage at the gate electrode g of the transistor 121 is converged toward the voltage (Vel−Vth) and is then changed to the voltage Vdata in the compensation period (D).

[Mathematical Equation 6]

Vgs=Vth−k₂(Vdata−Vref) (6)

Note that the coefficient k2 in Formula (6) is a coefficient determined by the capacity sizes Cblk and Cpix in a configuration (without the capacitive element 74) where the voltage Vdata of the data signal is not compressed. When the voltage Vgs is expressed as in Formula (6), the current Iel flowing in the OLED 130 can be expressed as in the following Formula (7).

$$\begin{matrix}[ Mathematical Equation 7 ] & \\ \begin{matrix}Iel = {k}_{1} {\{ Vth - {k}_{2} ( Vdata - Vref ) - Vth \}}^{2} \\ = {k}_{1} {{k}_{2} ( Vref - Vdata )}^{2}\end{matrix} & ( 7 )\end{matrix}$$

In Formula (7), the term corresponding to the threshold voltage Vth is omitted, and the current Iel is determined by the voltage Vdata of the data signal. Thus, degradation of the display quality due to the threshold voltage Vth of the transistor 121 can be suppressed.

In the embodiment, as can be actually seen in Formula (1), the voltage amplitude from the minimum value to the maximum value of the voltage Vdata of the data signal is compressed in accordance with the coefficient Ka, and the resultant voltage propagates to the gate electrode g.

In the present embodiment, the current Iel is limited with the voltage at the M level supplied to the gate electrode of the transistor 124 in the light emission period (F). Nevertheless, the degradation of the display quality due to the threshold voltage Vth can also be suppressed.

The effectiveness of the application of the voltage at the M level to the gate electrode of the transistor 124 in the light emission period (F) in the present embodiment will be described next.

The voltage at the M level is applied to the gate electrode of the transistor 124 to make the transistor 124 operate in a saturation range, so that the transistor 121 can maintain the ability of providing constant current regardless of the aging of the current-voltage characteristics of the OLED 130.

In particular, when the current Iel flows, the OLED 130 emits light with the luminance based on the current Iel. In the pixel circuits 110 of the present embodiment, the voltage of the gate electrode g of the transistor 121 is held by the capacitive element 140, whereby the current Iel flowing in the OLED 130 from the wire 116 can be guaranteed to be constant current.

However, the OLED 130 has the following characteristics. Specifically, the element characteristics change as the light emission time elapses, whereby a potential of the anode (pixel electrode 131) required for making the constant current flow gradually increases. An increase in the potential of the anode of the OLED 130 leads to a change in the equilibrium point of the potential in the path from the wire 116 to the common electrode 133, resulting in a rise in the potential of the source node of the transistor 124, that is, the drain node d of the transistor 121. An increase in the potential at the drain node d of the transistor 121 leads to a change in the voltage between the source node s and the drain node d of the transistor 121 and thus to a change in current flowing in the drain node of the transistor 121, resulting in the constantness of the current flowing in the OLED 130 being compromised.

Thus, in the present embodiment, the transistor 124 operates in the saturation range to suppress the degradation of the constantness of the current due to the aging of the element characteristics of the OLED 130.

When the transistor 124 operates in the saturation range, the transistor 124 is directly affected by the change in the potential at the anode of the OLED 130. The transistor 121 is affected by a change in the potential at the drain node of the transistor 124, but a change in the drain current in the saturation range is quite small. Thus, an impact of the change in the potential at the drain node of the transistor 121 coupled to the transistor 124 and of the change in the potential at the gate electrode due to current leakage is alleviated.

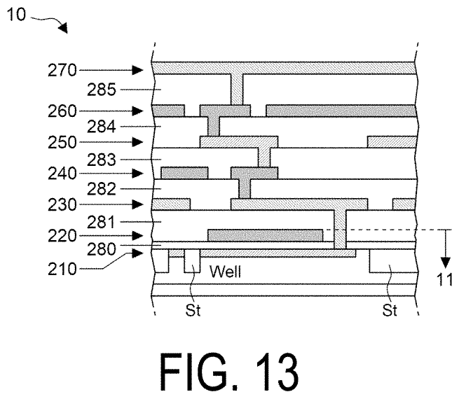

FIG. 13 is a cross-sectional view of a main part of the electro-optical device 10, and illustrates a structure of wires. FIG. 13 is a diagram simply illustrating wiring layers of the electro-optical device 10, and is not a cut away view of a particular part of the electro-optical device 10.

Layers used as conductive layers in the semiconductor substrate forming the electro-optical device 10 include a semiconductor layer 210, a gate electrode layer 220, a first wiring layer 230, a second wiring layer 240, a third wiring layer 250, a fourth wiring layer 260, and a pixel electrode layer 270 in this order in the Z direction as illustrated in FIG. 13.

For example, for the first wiring layer 230, the second wiring layer 240, the third wiring layer 250, and the fourth wiring layer 260, aluminum, an alloy including aluminum, or the like is used. For the pixel electrode layer 270, for example, indium tin oxide having permeability and conductivity is used.

Note that the ordinal numbers of wiring layers (first, second, third, and fourth) in the detailed description of embodiments indicate the order in which the layers are formed in the semiconductor substrate. On the other hand, the ordinal numbers of the wiring layers in claims are used for distinction between the wiring layers. Thus, the ordinal numbers of the wiring layers in the detailed description of embodiments do not necessarily match the ordinal numbers of the wiring layers in claims.

In the semiconductor layer 210, for example, the wires, transistor regions, electrodes, and the like are provided by implantation of impurity ions into a p well region Well. A gate insulating film 280 is provided between the semiconductor layer 210 and the gate electrode layer 220 in the Z direction.

The gate electrode layer 220 is patterned to form electrodes to be the gate electrodes of the transistors 121 to 124 and the other end of the capacitive element 140. Conduction between the electrode and the like of the semiconductor layer 210 and the electrode of the gate electrode layer 220 is achieved through a contact hole formed in the gate insulating film 280.

Functions of the transistors 121 to 124 are implemented by elements up to the gate electrode layer 220 in the Z direction in the semiconductor substrate. Thus, as illustrated in FIG. 13, the elements up to the gate electrode layer 220 in the electro-optical device 10 may be referred to as a substrate 11 for the sake of convenience. The Z direction (or the direction opposite to the Z direction) is the thickness direction of the substrate 11.

The first wiring layer 230, the second wiring layer 240, the third wiring layer 250, and the fourth wiring layer 260 are each patterned to have the wires, electrodes, and the like. The pixel electrode layer 270 is patterned to have the pixel electrode 131.

A first interlayer insulating film 281 is provided between the gate electrode layer 220 and the first wiring layer 230. Conduction between the electrode including the gate electrode layer 220 and the wire including the first wiring layer 230 and the like is achieved through a contact hole formed in the first interlayer insulating film 281.

A second interlayer insulating layer 282 is provided between the first wiring layer 230 and the second wiring layer 240. Conduction between the wire including the first wiring layer 230 and the like and the wire including the second wiring layer 240 and the like is achieved through a contact hole formed in the second interlayer insulating layer 282.

A third interlayer insulating film 283 is provided between the second wiring layer 240 and the third wiring layer 250. Conduction between the wire including the second wiring layer 240 and the like and the wire including the third wiring layer 250 and the like is achieved through a contact hole formed in the third interlayer insulating film 283.

A fourth interlayer insulating film 284 is provided between the third wiring layer 250 and the fourth wiring layer 260. Conduction between the wire including the third wiring layer 250 and the like and the wire including the fourth wiring layer 260 and the like is achieved through a contact hole formed in the fourth interlayer insulating film 284.

A fifth interlayer insulating film 285 is provided between the fourth wiring layer 260 and the pixel electrode layer 270. Conduction between the wire including the fourth wiring layer 260 and the like and the pixel electrode 131 including the pixel electrode layer 270 is achieved through a contact hole formed in the fifth interlayer insulating film 285.

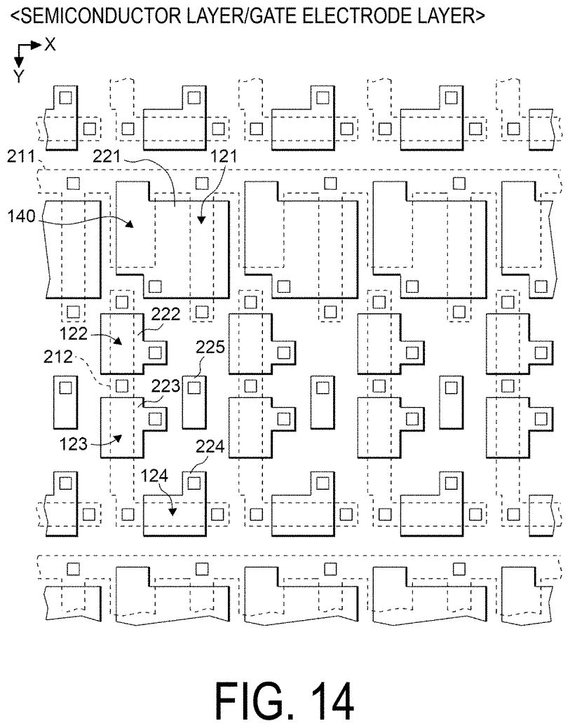

FIGS. 14 to 19 are plan views illustrating a specific wire structure of the electro-optical device 10.

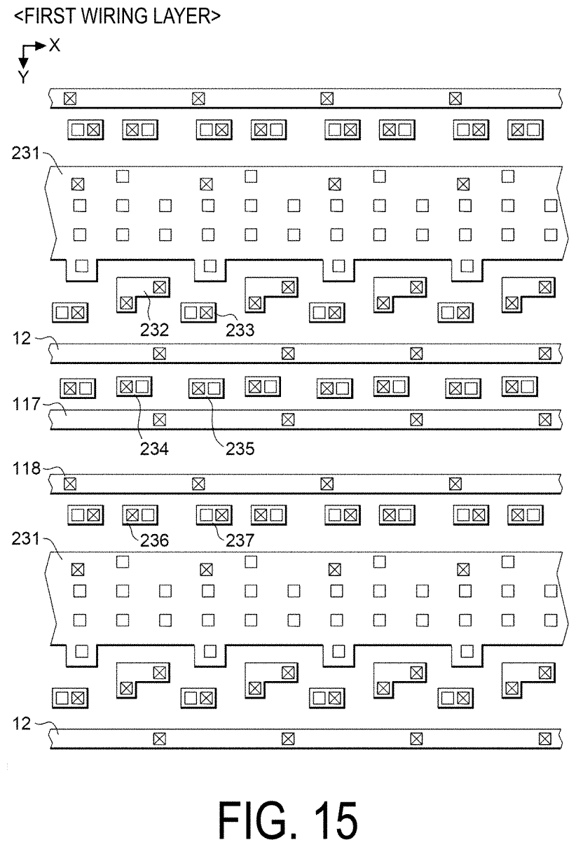

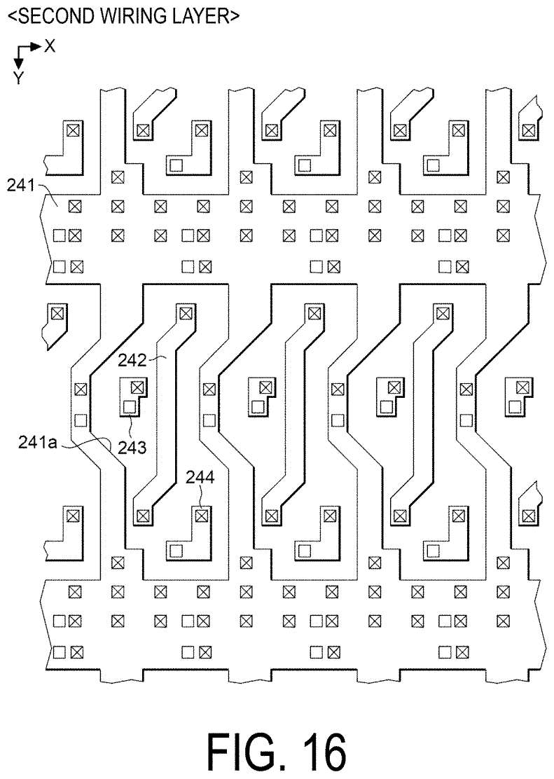

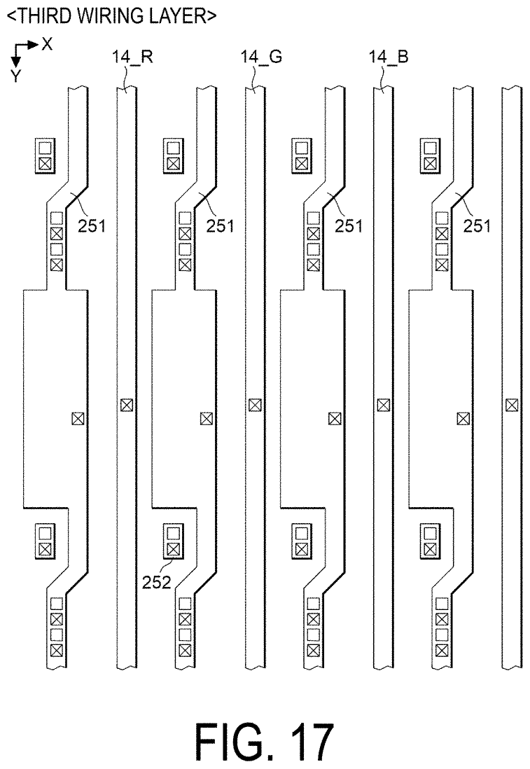

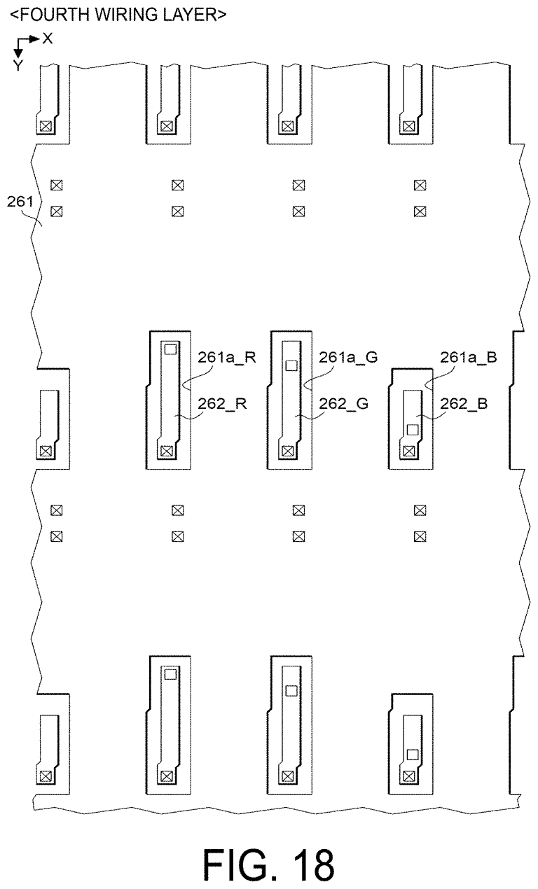

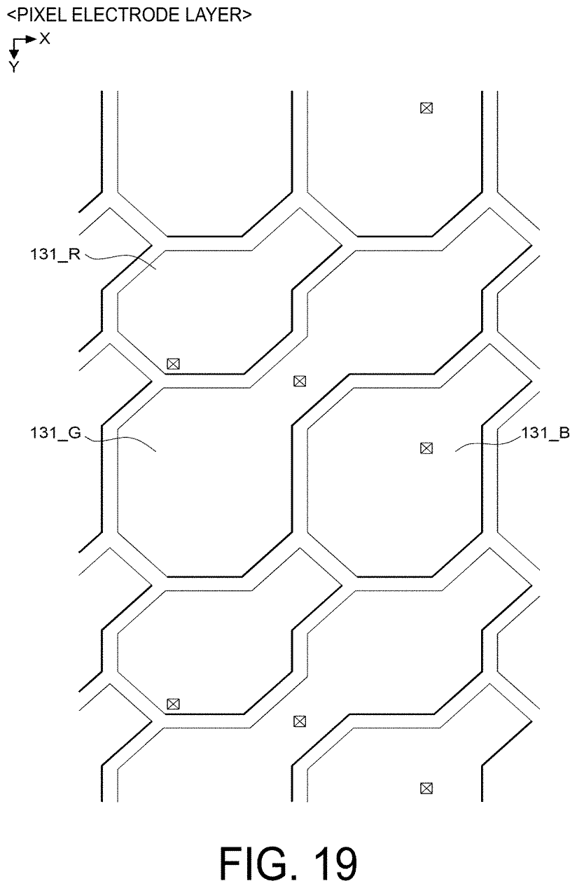

Specifically, FIG. 14 is a plan view illustrating a transistor region and a wire and the like formed in the semiconductor layer 210, and an electrode and the like formed by patterning the gate electrode layer 220. FIG. 15 is a plan view illustrating a wire and the like formed by patterning the first wiring layer 230. FIG. 16 is a plan view illustrating a wire and the like formed by patterning the second wiring layer 240. FIG. 17 is a plan view illustrating a wire and the like formed by patterning the third wiring layer 250. FIG. 18 is a plan view illustrating a wire and the like formed by patterning the fourth wiring layer 260. FIG. 19 is a plan view illustrating the pixel electrode 131 formed by patterning the pixel electrode layer 270.

In FIG. 14 to FIG. 19, a simple rectangle frame (with no × mark) indicates a position of a wire, electrode, or the like in the lower one of two wiring layers coupled to each other through the contact hole. A rectangle frame with a × mark indicates a position of a wire, electrode, or the like in the upper one of the two wiring layers coupled to each other through the contact hole.

Regarding the names of the parts, a layer . . . indicates a conductive layer after the film formation and before the patterning, or a layer collectively indicating a wire, electrode, and the like in the same conductive layer before the patterning. Furthermore, a wire . . . , an electrode . . . , and a relay member . . . are elements formed by patterning the layer . . . , and include the scanning lines 12, the data lines 14, and the control lines 117 and 118.

As illustrated in FIG. 14, the semiconductor layer 210 is provided with regions 211 and 212, and the gate electrode layer 220 is provided with electrodes 221 to 224.

The region 211 includes part of the wire 116, the semiconductor region of the transistor 121, and the other end of the capacitive element 140 by implantation of impurity ions into the p well region Well, for example.

Specifically, part of the region 211 extending in the X direction functions as the wire 116 and the source node of the transistor 121. Of two regions of the region 211 branched in the Y direction, one functions as a channel region and the drain node of the transistor 121, and the other one functions as the other end of the capacitive element 140.

The region 212 is the semiconductor region common to the transistors 122 to 124 formed by implantation of impurity ions, as in the case of the region 211.

The electrode 221 serves as both the gate electrode of the transistor 121 and one end of the capacitive element 140. A region where the electrode 221 and the region 211 overlap in plan view of the figure is the channel region of the transistor 121 and the capacitive element 140.

Note that plan view in the present description is a view of the electro-optical device 10 in a direction opposite to the Z direction.

The electrode 222 is a gate electrode of the transistor 122. A region where the electrode 222 and the region 212 overlap in plan view is the channel region of the transistor 122. The electrode 223 is a gate electrode of the transistor 123. A region where the electrode 223 and the region 212 overlap in plan view is the channel region of the transistor 123. The electrode 224 is a gate electrode of the transistor 124. A region where the electrode 224 and the region 212 overlap in plan view is the channel region of the transistor 124.

An electrode 225 is a pad for setting the substrate potential to the voltage Vel.

As illustrated in FIG. 15, a wire 231, the scanning lines 12, the control lines 117 and 118, and relay members 232 to 237 are provided by patterning the first wiring layer 230.

Each of the wire 231, the scanning lines 12, and the control lines 117 and 118 is provided for each row while extending in the X direction. Thus, each of the wire 231, the scanning lines 12, and the control lines 117 and 118 is commonly provided to the pixel circuits 110 of a single row (5760 circuits).

The wire 231 is disposed between the scanning lines 12 adjacent to each other in the Y direction as illustrated in the figure.

The wire 231 is electrically coupled to part of the region 211 in FIG. 14 extending in the X direction through the contact hole. As described below, the voltage Vel is directly or indirectly applied to the wire 231. Thus, the wire 231 has a larger width in the Y direction than the scanning lines 12 and the control lines 117 and 118 also extending in the X direction, to reduce the wire resistance.

The scanning lines 12 are electrically coupled to the electrode 222 through the contact hole. The control line 117 is electrically coupled to the electrode 223 through the contact hole, and the control line 118 is electrically coupled to the electrode 224 through the contact hole.

The relay member 232 relays between the electrode 221 and part of the region 212 to be the drain node of the transistor 122 through the contact hole in FIG. 14. Thus, the drain node of the transistor 122 is electrically coupled to the gate electrode g of the transistor 121 and one end of the capacitive element 140.

The relay member 233 is electrically coupled to part of the region 212 in FIG. 14 to be the drain node of the transistor 121 through the contact hole.

The relay member 234 is electrically coupled to a coupling point between the source node of the transistor 122 and the drain node of the transistor 123 in the region 212 in FIG. 14 through the contact hole.

The relay member 235 is electrically coupled to the electrode 225 in FIG. 14 through the contact hole.

The relay member 236 is electrically coupled to a coupling point between the source node of the transistor 123 and the source node of the transistor 124 in the region 212 in FIG. 14 through the contact hole.

The relay member 237 is electrically coupled to part of the region 212 in FIG. 14 to be the drain node of the transistor 124 through the contact hole.

As illustrated in FIG. 16, a wire 241 and relay members 242 to 244 are provided by patterning the second wiring layer 240.

The wire 241 extends in the X direction and the Y direction, is commonly provided for the pixel circuits 110 that are arrayed in 1080 rows×5760 columns, and is electrically coupled to the wire 231 in FIG. 15 through a plurality of contact holes. The wire 241 is provided with open regions 241a corresponding one to one to the pixel circuits 110. In other words, the wire 241 extends in the X direction and the Y direction to be in a lattice form in plan view.

The relay members 242 to 244 are provided to each of the regions 241a in plan view. In other words, the relay members 242 to 244 are each surrounded by the wire 241 in the second wiring layer 240. The relay member 242 substantially extends in the Y direction, has one end electrically coupled to the relay member 233 in FIG. 15 through the contact hole, and has the other end electrically coupled to the relay member 236 in FIG. 15 through the contact hole. Thus, the drain node d of the transistor 121 is electrically coupled to the source node of the transistor 123 and the source node of the transistor 124, through the relay members 233, 242, and 236 in this order.

The relay member 243 is electrically coupled to the relay member 234 in FIG. 15 through the contact hole. The relay member 244 is electrically coupled to the relay member 237 in FIG. 15 through the contact hole.

As illustrated in FIG. 17, a wire 251, a relay member 252, and data lines 14_R, 14_G, and 14_B are provided by patterning the third wiring layer 250.

Each of the data lines 14_R, 14_G, and 14_B extends in the Y direction and is provided for each column. Specifically, the data line 14_R is a data line, out of the data lines 14, corresponding to the column of the pixel circuit 110R, and is generally a data line corresponding to the (3j−2)th column. The data line 14_G is a data line corresponding to the column of the pixel circuit 110G, and is generally a data line corresponding to the (3j−1)th column. The data line 14_B is a data line corresponding to the column of the pixel circuit 110B, and is generally a data line corresponding to the (3j)th column.

The data lines 14_R, 14_G, and 14_B have the same structure, but the structure for and after the fourth wiring layer 260 differs among the colors, and thus are denoted by reference numerals corresponding to different colors. When the data lines 14_R, 14_G, and 14_B are generally described without specifying their colors, the data lines are denoted by reference numeral 14 as in the above description.

The data line 14 is electrically coupled to the relay member 243 in FIG. 16 through the contact hole. Thus, the data line 14 is electrically coupled to the source node of the transistor 122 and the drain node of the transistor 123 through the relay members 243 and 234 in this order.

The wire 251 extends in the Y direction to be provided for each column, between the adjacent data lines 14. Thus, the wire 251 is commonly provided for the pixel circuits 110 of each column (1080 circuits). The wire 251 is coupled to the wire 241 in FIG. 16 through the contact hole. The relay member 252 is provided for each pixel circuit 110 between the adjacent data lines 14, and is electrically coupled to the relay member 244 in FIG. 16 through the contact hole.

As illustrated in FIG. 18, a wire 261 and relay members 262_R, 262_G, and 262_B are provided by patterning the fourth wiring layer 260.

The wire 261 extends in the X direction and the Y direction, is commonly provided for the pixel circuits 110 that are arrayed in 1080 rows×5760 columns, and is electrically coupled to the wire 251 in FIG. 17 through a plurality of contact holes. Thus, the wires 231, 241, 251, and 261 are electrically coupled to each other to be a common coupling body. Thus, when the voltage Vel is applied to at least one of the wires 231, 241, 251, and 261 through an external terminal not illustrated, the voltage Vel is applied as the substrate potential through the relay member 235 and the electrode 225 in this order from the wire 241, which is the common coupling body. The voltage Vel is applied to the part of the region 211 extending in the X direction and functioning as the other end of the capacitive element 140, through the wire 231, which is the common coupling body. Thus, the voltage Vel is applied to the source node of the transistor 121 and the other end of the capacitive element 140.

The wire 261 is provided with an open region 261a_R corresponding to the pixel circuit 110R. Similarly, the wire 261 is provided with an open region 261a_G and an open region 261a_B respectively corresponding to the pixel circuits 110G and 110B.

The relay member 262_R is a relay wire provided in the region 261a_R corresponding to the pixel circuit 11CR in plan view. The relay member 262_R is electrically coupled to the relay member 252 in FIG. 17 through the contact hole.

The relay member 262_G is a relay wire provided in the region 261a_G corresponding to the pixel circuit 110G in plan view. The relay member 262_G is electrically coupled to the relay member 252 in FIG. 17 through the contact hole.

The relay member 262_B is a relay wire provided in the region 261a_B corresponding to the pixel circuit 110B in plan view. The relay member 262_B is electrically coupled to the relay member 252 in FIG. 17 through the contact hole.

In other words, the wire 261 extends in the X direction and the Y direction to be in a lattice form, and the relay members 262_R, 262_G, and 262_B are each surrounded by the wire 261 in the fourth wiring layer 260 in plan view.

The relay members 262_R, 262_G, and 262_B are denoted by reference numeral 262, when being generally described without specifying their colors. Thus, the relay member 262 is surrounded by the wire 261 in the fourth wiring layer 260.

As illustrated in FIG. 19, pixel electrodes 131_R, 131_G, and 131_B are provided by patterning the pixel electrode layer 270.

The pixel electrode 131_R is electrically coupled to the relay member 262_R in FIG. 18 through the contact hole. Thus, the pixel electrode 131_R is electrically coupled to the drain node of the transistor 124 in the pixel circuit 110R, through the relay members 262_R, 252, 244, and 237 in this order.

The pixel electrode 131_G is electrically coupled to the relay member 262_G in FIG. 18 through the contact hole. Thus, the pixel electrode 131_G is electrically coupled to the drain node of the transistor 124 in the pixel circuit 110G, through the relay members 262_G, 252, 244, and 237 in this order.

The pixel electrode 131_B is electrically coupled to the relay member 262_B in FIG. 18 through the contact hole. Thus, the pixel electrode 131_B is electrically coupled to the drain node of the transistor 124 in the pixel circuit 110B, through the relay members 262_B, 252, 244, and 237 in this order.

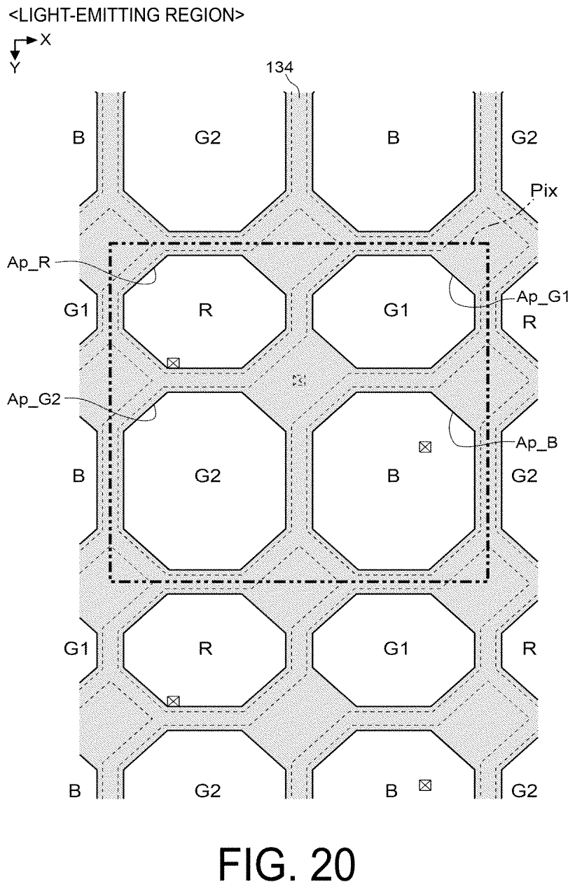

FIG. 20 is a plan view illustrating arrangement of light-emitting regions R, G1, G2, and B in the display region 100. The red light-emitting region R is a region of the pixel electrode 131_R that is in contact with the light-emitting layer 132. The green light-emitting region is divided into the regions G1 and G2. The light-emitting regions G1 and G2 are regions in the pixel electrode 131_G that are in contact with the light-emitting layer 132. The light-emitting region B is a region in the pixel electrode 131_B that is in contact with the light-emitting layer 132.

The light-emitting regions R, G1, G2, and B are defined by opening portions Ap_R, Ap_G1, Ap_G2, and Ap_B in order. The opening portions Ap_R, Ap_G1, Ap_G2, and Ap_B are formed by patterning a pixel separation layer provided to cover the pixel electrodes 131_R, 131_G, and 131_B as described below.

Note that, one color dot is expressed through additive color mixing of light generated from the light-emitting regions R, G1, G2, and B surrounded by a frame Pix in the figure.

In plan view, the area of the light-emitting region B is greater than the area of the light-emitting region R. The area of the light-emitting region R is substantially the same as that of the light-emitting region G1, and the area of the light-emitting region B is substantially the same as that of the light-emitting region G2. Thus, the sum of the areas of the light-emitting region G1 and the light-emitting region G2 is greater than the area of the light-emitting region B.

Since the light emission efficiency of red is the highest among red, green, and blue, the area of the light-emitting region R is the smallest among the three colors. Since the visibility of green is the highest among red, green, and blue, and for the sake of longer service life, the area of the green light-emitting region, that is, the sum of the area of the light-emitting region G1 and the area of the light-emitting region G2 is the largest among the three colors.

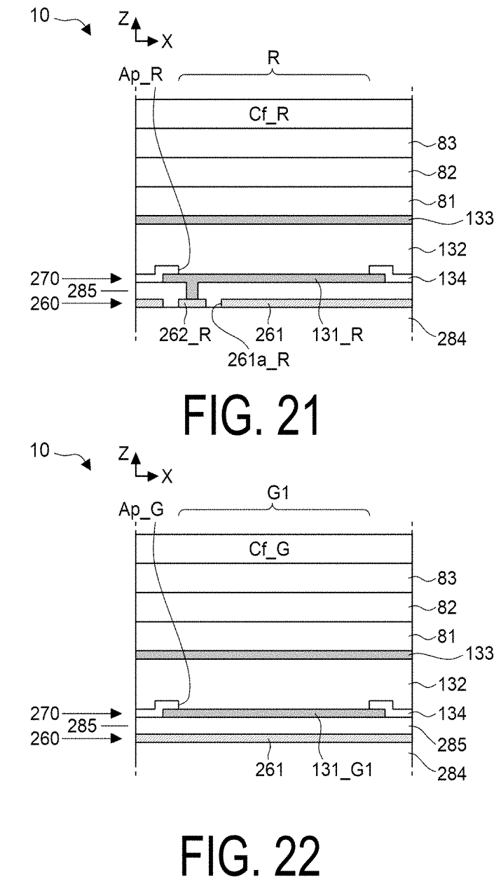

FIGS. 21 to 23 are cross-sectional views of main parts illustrating the configuration of the electro-optical device 10 formed above the fourth wiring layer 260. Of the figures, FIG. 21 is a cross-sectional view of the light-emitting region R in the electro-optical device 10, taken along a line in the X direction and including the contact hole coupling the pixel electrode 131_R with the relay member 262_R.

The pixel electrode 131_R has light transmissive properties, and is laminated on the fifth interlayer insulating film 285.

A pixel separation film 134 is laminated on the fifth interlayer insulating film 285 or the pixel electrode 131_R, and is an insulating film provided to cover a circumference edge portion of the pixel electrode 131_R. In the light-emitting region R, the pixel separation film 134 has the opening portion Ap_R opening in a shape as illustrated in FIG. 20 in plan view. For example, silicon oxide is used as the pixel separation film 134.

The light-emitting layer 132 is laminated on the pixel electrode 131_R or the pixel separation film 134. The light-emitting layer 132 is not particularly illustrated, includes a hole injection layer, a hole transport layer, an organic light-emitting layer, and an electron transport layer and is common to all the display regions for R, G, and B.

The common electrode 133 is a conductive layer having light transmissive properties and reflectivity. The common electrode 133 is provided to cover the light-emitting layer 132 and is common in all the regions including the light-emitting regions R, G, and B. For example, an alloy of Mg and Ag is used as the common electrode 133.

The light-emitting layer 132 is a region on the pixel electrode 131_R that is not covered by the pixel separation film 134, that is, a region that is in contact with the pixel electrode 131_R, and holes are supplied from a region defined by the opening portion Ap_R to emit white light.

Although not elaborated in FIG. 21, a reflective layer that reflects the light emitted in the direction opposite to the Z direction in the Z direction is provided between the pixel electrode 131_R and the fourth wiring layer 260. The optical distance between the reflective layer and the common electrode 133 is adjusted in accordance with the wavelength of red light, whereby a function of an optical resonator is provided. Specifically, the white light emitted from the light-emitting layer 132 is repeatedly reflected between the reflective layer and the common electrode 133_R. As a result, the intensity of light having a wavelength corresponding to the optical distance is enhanced, and this light is emitted in the Z direction. As an example, in the optical resonator corresponding to the light-emitting region R, the intensity of light having a wavelength of 610 nm is enhanced. The enhanced light passes through the common electrode 133 and is emitted as red light in the Z direction through a colored layer Cf_R.

In this way, light including a red component is emitted from the light-emitting region R in the Z direction in plan view.

A first sealing layer 81 is an insulating film having light transmissive properties and is provided to cover the common electrode 133.

A planarized layer 82 is an insulating film having light transmissive properties, and is provided to cover the first sealing layer 81 so that an observation surface is flat without any step. For example, an organic material such as an epoxy resin is used as the planarized layer 82.

A second sealing layer 83 is an insulating film having light transmissive properties, and is provided to cover the planarized layer 82. The first sealing layer 81 and the second sealing layer 83 are provided to prevent moisture and oxygen from entering the light-emitting layer 132. For example, silicon oxynitride (SiON) is used as the first sealing layer 81 and the second sealing layer 83.

In the region including the light-emitting region R in plan view, the colored layer Cf_R is provided to cover the second sealing layer 83. The colored layer Cf_R is provided by patterning a photosensitive resin including a pigment that transmits red light using a photolithography technique.

FIG. 22 is a cross-sectional view of the light-emitting region G1 in the electro-optical device 10, taken along a line in the X direction at a position in the Y direction that is the same as that in FIG. 21.

The contact hole coupling the pixel electrode 131_G with the relay member 262_G is included in none of the light-emitting regions G1 and G2 in plan view as illustrated in FIG. 20, and thus is not illustrated in FIG. 22.

Although not elaborated in FIG. 22, a reflective layer that reflects the light emitted in the direction opposite to the Z direction in the Z direction is provided between the pixel electrode 131_G and the fourth wiring layer 260, to function as an optical resonator. The optical distance between the reflective layer provided corresponding to the light-emitting region R and the common electrode 133 is adjusted in accordance with the wavelength of green light. As an example, in the optical resonator corresponding to the light-emitting region G, the intensity of light having a wavelength of 540 nm is enhanced. The enhanced light passes through the common electrode 133 and is emitted as green light in the Z direction through a colored layer Cf_G.

The structure of the light-emitting region G2 is substantially the same as that of the light-emitting region G1.

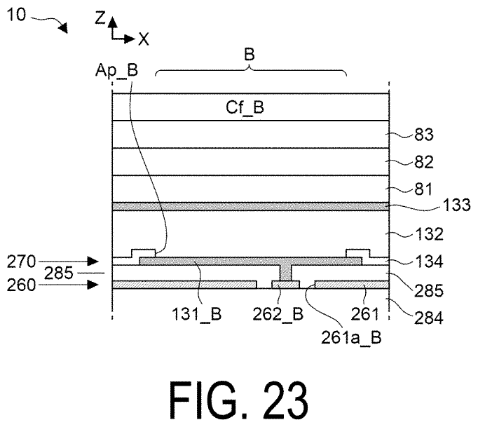

FIG. 23 is a cross-sectional view of the light-emitting region B in the electro-optical device 10, taken along a line in the X direction and including the contact hole coupling the pixel electrode 131_B with the relay member 262_B.

Although not elaborated in FIG. 23, a reflective layer that reflects the light emitted in the direction opposite to the Z direction in the Z direction is provided between the pixel electrode 131_B and the fourth wiring layer 260, to function as an optical resonator. The optical distance between the reflective layer provided corresponding to the light-emitting region B and the common electrode 133 is adjusted in accordance with the wavelength of blue light. As an example, in the optical resonator corresponding to the light-emitting region B, the intensity of light having a wavelength of 470 nm is enhanced. The enhanced light passes through the common electrode 133 and is emitted as blue light in the Z direction through a colored layer Cf_B.

Furthermore, a filling layer, protective glass, and the like are provided on the colored layers Cf_R, Cf_G, and Cf_B, but they will not be described because they are not important in this case.

In the embodiment, the wire 231 is provided between the scanning lines 12 adjacent to each other in plan view as illustrated in FIG. 15, and the wire 251 is provided between the data lines 14 adjacent to each other in plan view as illustrated in FIG. 17. Thus, in the first wiring layer 230, interference in the Y direction is suppressed by the wire 231 to which the voltage Vel is applied, and in the second wiring layer 240, the interference in the X direction is suppressed by the wire 251 to which the voltage Vel is applied. The wire 231 is provided together with the scanning lines 12 in the first wiring layer 230, and the wire 251 is provided together with the data lines 14 in the third wiring layer 250, and thus no wiring layer needs to be separately provided.

In the embodiment, as illustrated in FIG. 16, the wire 241 to which the voltage Vel is applied is formed to be in a lattice shape. Thus, in the second wiring layer 240, the relay members 242 to 244 surrounded by the wire 241 are less susceptible to the interference in both the X direction and the Y direction.

Similarly, as illustrated in FIG. 18, since the wire 261 to which the voltage Vel is applied is formed in a lattice shape, the relay member 262 surrounded by the wire 261 in the fourth wiring layer 260 is less susceptible to interference in both the X direction and the Y direction.

Thus, in the embodiment, the wire 231 suppresses the interference in the Y direction in the first wiring layer 230, the wire 241 suppresses the interference in the X direction and the Y direction in the second wiring layer 240, the wire 251 suppresses the interference in the X direction in the third wiring layer 250, and the wire 261 suppresses the interference in the X direction and the Y direction in the fourth wiring layer 260.

The wires 231, 241, 251, and 261 electrically coupled to each other through the contact holes are a common coupling body coupled in parallel. Thus, the wiring resistance of the common coupling body to which the voltage Vel is applied can be reduced.

The current to the OLED 130 flows in a path from the drain node d of the transistor 121 to the pixel electrode 131. When there is interference in this path, current fails to appropriately flow, and thus the display quality is negatively affected. In the embodiment, the electrical coupling is established from the drain node of the transistor 121 to the pixel electrode 131, sequentially through the relay members 237, 244, and 252. The relay member 237 is provided between the control line 118 and the wire 231 in plan view, and the relay member 244 is surrounded by the wire 241 in plan view. Thus, interference is suppressed, whereby the negative impact on the display quality is reduced.

The control signal /Gcmp(i) is supplied to the control line 117 in the i-th row. This control signal /Gcmp(i) is constantly at the H level, except for the horizontal scanning period (H) in which the i-th row is selected.

The control signal /Gel (i) is supplied to the control line 118 in the i-th row. As illustrated in FIG. 6, the control signal /Gel (i) involves a voltage change in a period in which the i-th row is not selected, but the frequency of such a voltage change is low compared with the data lines 14.

Thus, the control lines 117 and 118 function as shield wires in a period with a constant voltage, and thus the relay members 232 to 237 provided to the first wiring layer 230 are less susceptible to interference in the Y direction.

In the period in which the i-th row is not selected, the voltage amplitude of the control signal /Gel(i) is small compared with logical signals such as the other control signals and scanning signals. Thus, the level of interference due to the voltage change of the control signal /Gel(i) is low compared with the other logical signals.

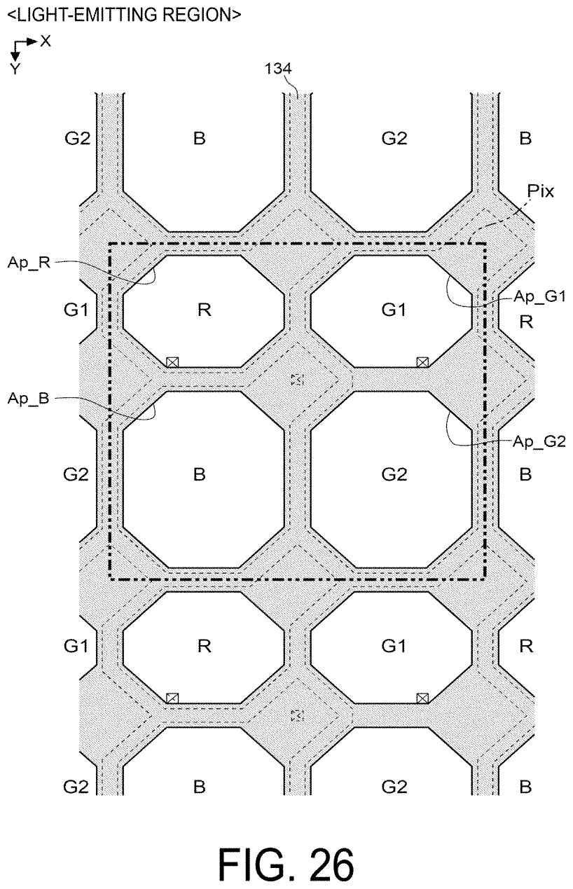

In the embodiment, the light-emitting regions R, G1, G2, and B in one color pixel are in a configuration as illustrated in FIG. 20 in plan view, that is, in a configuration in which the light-emitting regions G1 and G2 are obliquely arranged relative to the Y direction, but such an arrangement should not be construed in a limiting sense. For example, as in a modification illustrated in FIG. 26, the light-emitting regions G1 and G2 may be arranged along the Y direction.

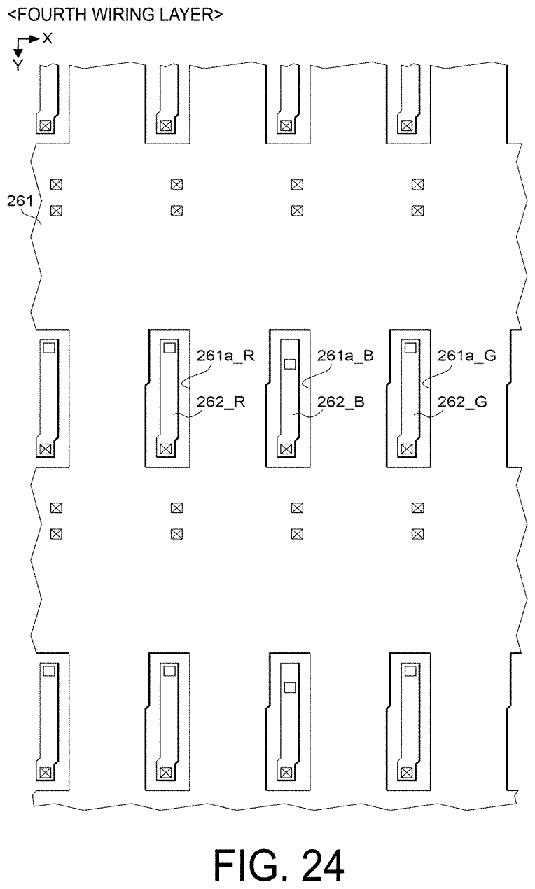

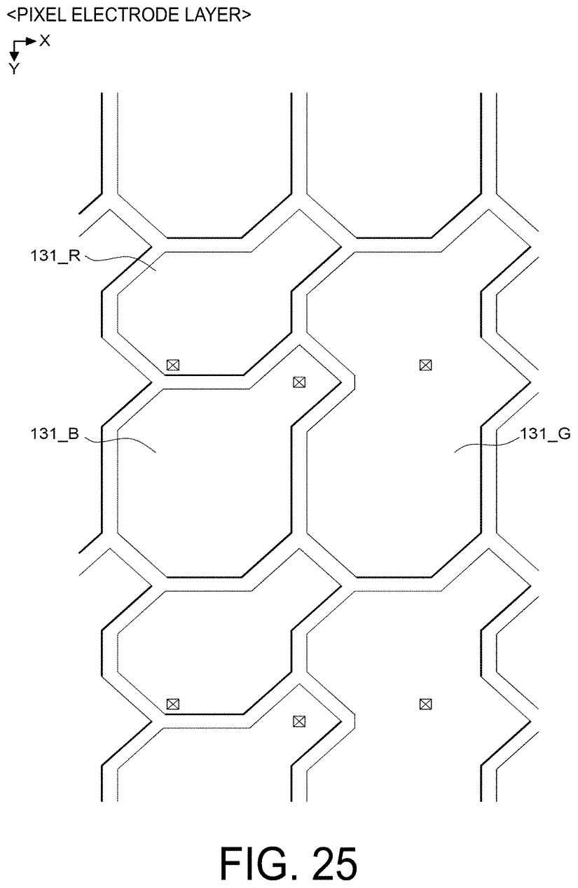

FIG. 24 illustrates the wire 261 and the relay members 262_R, 262_G, and 262_B provided by patterning the fourth wiring layer 260 in this modification. FIG. 25 illustrates the pixel electrode 131_R, 131_G, and 131_B provided by patterning the pixel electrode layer 270.

The data lines 14 are arrayed, in the X direction, in the order of RGB in the embodiment, but are arrayed in the order of RBG in the modification.

In the embodiment, the relay members 262_R and 262_G have substantially the same shape, the relay member 262_B has a shape shorter than the relay members 262_R and 262_G. In the modification, the relay members 262_R, 262_G, and 262_B have substantially the same shape. Thus, the regions 261a_R, 261a_B, and 261a_G open in the wire 261 have substantially the same shape.

In the modification, the position of the contact hole electrically coupled to the pixel electrode 131_R in the relay member 262_R and the position of the contact hole electrically coupled to the pixel electrode 131_G in the relay member 262_G are substantially the same. The position of the contact hole electrically coupled to the pixel electrode 131_B in the relay member 262_B is shifted from those in the relay members 262_R and 262_G in the Y direction.

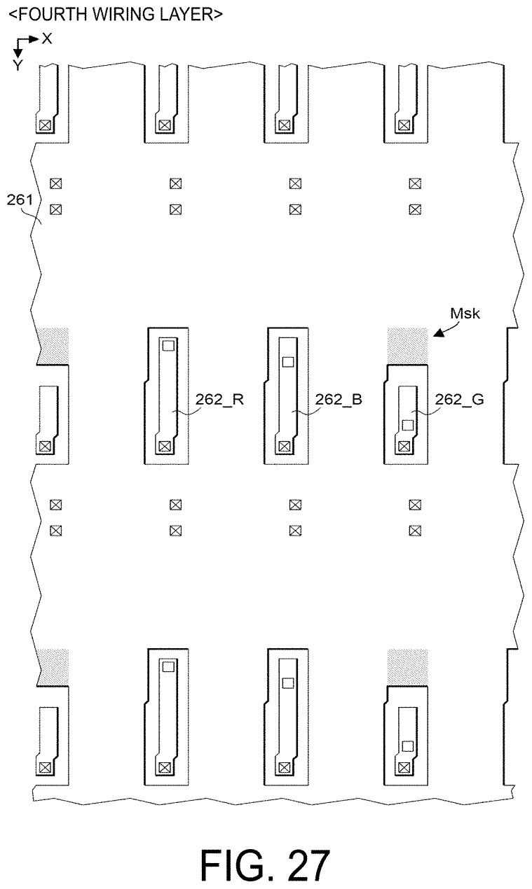

Comparison in the wire 261 between the embodiment and the modification indicates that, as illustrated in FIG. 27, a region Msk hatched in the wire 261 remains in the embodiment, whereas the wire 261 has no portion corresponding to the region Msk in the modification. Thus, in the embodiment, the area of the region open in the wire 261 is small, and thus the light blocking performance for the transistors 121 to 124 is high, compared with the modification. Thus, in the embodiment, the light leakage current is low and thus the negative impact on the display quality is small, compared with the modification.

In the embodiment and the modification (hereinafter, referred to as “the above-described exemplary embodiments”), the OLED 130 is described as an example of the light-emitting element, but other light-emitting elements may be used. For example, an LED, a mini LED, a micro LED, or the like may be used as the light-emitting element.

The channel types of the transistors 121, 122, 123, and 124 are not limited to those in the above-described exemplary embodiments. These transistors may also be replaced with a transmission gate as appropriate except for the transistor 121. The transmission gates 45, 72, 73 may also be replaced with a transistor of a single channel.

Electronic Apparatus

Next, an electronic apparatus to which the electro-optical device 10 according to the above-described exemplary embodiments is applied will be described. The electro-optical device 10 is suitable for application with a small pixel and high definition display. Therefore, a head-mounted display will be described as an example of the electronic apparatus.

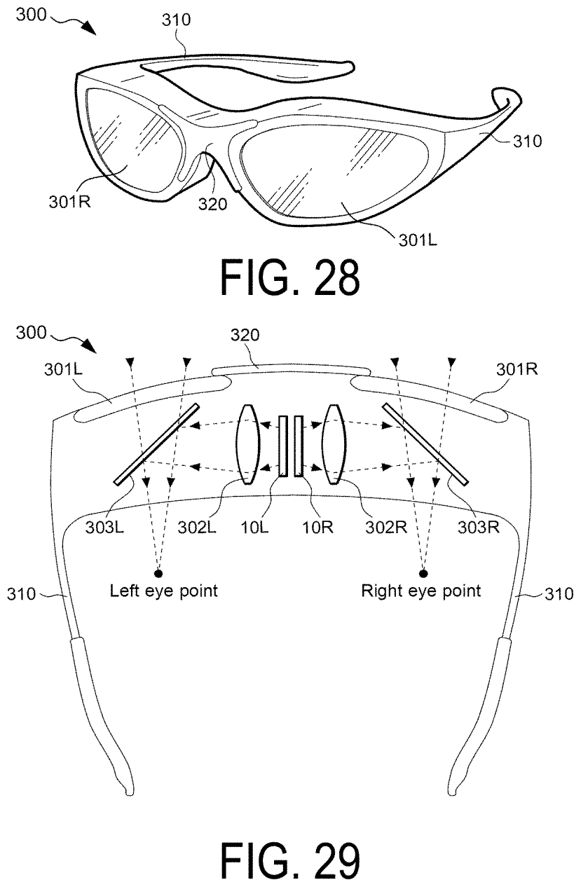

FIG. 28 is a view illustrating an exterior of a head-mounted display, and FIG. 29 is a view illustrating an optical configuration of the head-mounted display.

First, as illustrated in FIG. 28, a head-mounted display 300 includes, in terms of exterior, temples 310, a bridge 320, and lenses 301L and 301R, similar to typical eye glasses. In addition, as illustrated in FIG. 29, in the head-mounted display 300, an electro-optical device 10L for a left eye and an electro-optical device 1CR for a right eye are provided in the vicinity of the bridge 320 and on the back side (the lower side in the drawing) of the lenses 301L and 301R.

An image display surface of the electro-optical device 10L is disposed to be on the left side in FIG. 29. Thus, a display image by the electro-optical device 10L is output via an optical lens 302L in a 9-o'clock direction in the drawing. A half mirror 303L reflects the display image by the electro-optical device 10L in a 6-o'clock direction, while the half mirror 303L transmits light incident in a 12-o'clock direction. An image display surface of the electro-optical device 1CR is disposed on the right side opposite to the electro-optical device 10L. Thus, the display image by the electro-optical device 1CR is output via the optical lens 302R in a 3-o'clock direction in the drawing. A half mirror 303R reflects the display image by the electro-optical device 1CR in a 6-o'clock direction, while the half the mirror 303R transmits light incident in a 12-o'clock direction.

In this configuration, a wearer of the head-mounted display 300 can observe the display images by the electro-optical devices 10L and 1CR in a see-through state in which the display images by the electro-optical devices 10L and 1CR overlap the outside.

In addition, in the head-mounted display 300, in the images for both eyes with parallax, an image for a left eye is displayed on the electro-optical device 10L, and an image for a right eye is displayed on the electro-optical device 10R, and thus, it is possible to cause the wearer to sense the displayed images as an image displayed having a depth or a three-dimensional effect.

In addition to the head mounted display 300, the electric apparatus including the electro-optical device 10 can be applied to an electronic viewing finder in a video camera, a lens-exchangeable digital camera, or the like, a mobile information terminal, a wristwatch display, a light valve for a projection type projector, and the like.

Supplementary Note

Preferred aspects of the present disclosure are understood from the above description, as follows. In the following, in order to facilitate understanding of each of the aspects, the reference signs of the drawings are provided in parentheses for convenience, but the present disclosure is not intended to be limited to the illustrated aspects.

### APPENDIX 1

An electro-optical device (10) according to one aspect (aspect 1) includes: a substrate (11) provided with a first transistor (121), a light-emitting element (130) including a pixel electrode (131), a plurality of power supply wires (231, 241, 251, 261) that are provided in a plurality of wiring layers (230, 240, 250, 260) between the substrate (11) and the pixel electrode (131) in a thickness direction (Z direction) of the substrate (11), and are used by the first transistor (121) to supply current to the light-emitting element (130), a scanning line (12) that is provided in a first wiring layer (230) of the plurality of wiring layers (230, 240, 250, 260) and extends in a first direction (X direction), and a data line (14) that is provided in a second wiring layer (250) of the plurality of wiring layers (230, 240, 250, 260) and extends in a second direction (Y direction), in which the plurality of power supply wires (231, 241, 251, 261) include a first power supply wire (231) and a second power supply wire (251), the first power supply wire (231) is provided in the first wiring layer (230) and extends in the first direction (X direction), and the second power supply wire (251) is provided in the second wiring layer (250) and extends in the second direction (Y direction).

According to aspect 1, interference in a direction orthogonal to the first direction in the first wiring layer (230) is suppressed by the first power supply wire (231), and interference in a direction orthogonal to the second direction in the second wiring layer (250) is suppressed by the second power supply wire (251).

Also in aspect 1, the first power supply wire (231) is provided together with the scanning line (12) from the first wiring layer (230), and the second power supply wire (251) is provided together with the data line (14) from the second wiring layer (250), and thus no wiring layer needs to be separately provided.

### APPENDIX 2

In the electro-optical device (10) according to aspect 2 that is a specific aspect of aspect 1, in plan view, the first power supply wire (231) is provided between two adjacent ones of the scanning lines (12), and the second power supply wire (251) is provided between two adjacent ones of the data lines (14). According to aspect 2, interference due to the two adjacent scanning lines (12) is suppressed, and interference due to the two adjacent data lines (14) is suppressed.

### APPENDIX 3

In the electro-optical device (10) according to aspect 3 that is a specific aspect of aspect 1 or 2, the plurality of power supply wires (231, 241, 251, 261) are provided in each of the plurality of wiring layers (230, 240, 250, 260) to extend in at least one of the first direction (X direction) and the second direction (Y direction).

According to aspect 3, interference in the direction orthogonal to the first direction (the X direction) or interference in the direction orthogonal to the second direction (Y direction) are suppressed in each of the plurality of wiring layers (230, 240, 250, 260).

### APPENDIX 4

In the electro-optical device (10) according to aspect 4 that is a specific aspect of any one of aspects 1 to 3, the plurality of power supply wires (231, 241, 251, 261) include a third power supply wire (241 or 261) provided in a third wiring layer (240 or 260) of the plurality of wiring layers (230, 240, 250, 260), and the third power supply wire (241 or 261) is provided in a lattice shape extending in the first direction (X direction) and the second direction (Y direction).

According to aspect 4, not only interference in the direction orthogonal to the first direction (the X direction) but also interference in the direction orthogonal to the second direction (Y direction) is suppressed in the third wiring layer (240 or 260).

### APPENDIX 5

The electro-optical device (10) according to aspect 5 that is a specific aspect of aspect 4 further includes a relay member (244 or 262) that is provided in the third wiring layer (240 or 260) to establish electrical coupling between the first transistor (121) and the pixel electrode (131), in which the relay member (244 or 262) is surrounded by the third power supply wire (241 or 261) in plan view.

Since the current to the light-emitting element (130) flows in a path from the first transistor (121) to the pixel electrode (131), when there is interference in this path, the display quality is negatively affected. According to aspect 5, not only interference in the direction orthogonal to the first direction (the X direction) but also interference in the direction orthogonal to the second direction (Y direction) is suppressed in the third wiring layer (240 or 260), and thus the negative impact on the display quality is reduced.

### APPENDIX 6

In the electro-optical device (10) according to aspect 6 that is a specific aspect of aspect 4 or 5, the first power supply wire (231), the second power supply wire (251), and the third power supply wire (241 or 261) are electrically coupled through one or more contact holes.

According to aspect 6, the first power supply wire (231), the second power supply wire (251), and the third power supply wire (241 or 261) are coupled in parallel, whereby wiring resistance is reduced.

### APPENDIX 7

In the electro-optical device (10) according to aspect 7 that is a specific aspect of any one of aspects 1 to 5, the substrate (11) is provided with a second transistor (122), a third transistor (123), and a fourth transistor (124), the second transistor has a gate electrode coupled to the scanning line (12), the third transistor has a gate electrode coupled to a first control line (117), the fourth transistor has a gate electrode coupled to a second control line (118), the first control line (117) is provided in the first wiring layer (230) to extend in the first direction (X direction), and the second control line (118) is provided in the first wiring layer (230) to extend in the first direction (X direction).

The first control line (117) and the second control line (118) involve a voltage change unlike the power supply wires, but the frequency of such a voltage change is low compared with the data lines (14), and the voltage is constant over a plurality of horizontal scanning period (H). Thus, the first control line (117) and the second control line (118) function as a type of shield wires in a period with a constant voltage, and thus interference in the direction orthogonal to the first direction (X direction) is suppressed.

### APPENDIX 8

An electronic apparatus (300) according to aspect 8 includes the electro-optical device (10) described in any one of aspects 1 to 7.

What is claimed is:

1. An electro-optical device comprising:
a substrate provided with a first transistor;
a light-emitting element including a pixel electrode; a plurality of power supply wires that are provided at a plurality of wiring layers between the substrate and the pixel electrode in a thickness direction of the substrate, and are used by the first transistor to supply current to the light-emitting element;
a scanning line that is provided in a first wiring layer of the plurality of wiring layers and extends in a first direction; and
a data line that is provided in a second wiring layer of the plurality of wiring layers and extends in a second direction, wherein
the plurality of power supply wires include a first power supply wire and a second power supply wire,
the first power supply wire is provided in the first wiring layer and extends in the first direction, and
the second power supply wire is provided in the second wiring layer and extends in the second direction.

2. The electro-optical device according to claim 1, wherein
in plan view,
the first power supply wire is provided between two adjacent ones of the scanning lines, and
the second power supply wire is provided between two adjacent ones of the data lines.

3. The electro-optical device according to claim 1, wherein the plurality of power supply wires are provided in each of the plurality of wiring layers and extend in at least one of the first direction and the second direction.

4. The electro-optical device according to claim 1, wherein
the plurality of power supply wires include a third power supply wire provided in a third wiring layer of the plurality of wiring layers, and
the third power supply wire is provided in a lattice shape extending in the first direction and the second direction.

5. The electro-optical device according to claim 4 further comprising a relay member that is provided in the third wiring layer to establish electrical coupling between the first transistor and the pixel electrode, wherein
the relay member is surrounded by the third power supply wire in plan view.

6. The electro-optical device according to claim 4, wherein the first power supply wire, the second power supply wire, and the third power supply wire are electrically coupled through one or more contact holes.

7. The electro-optical device according to claim 1, wherein
the substrate is provided with a second transistor, a third transistor, and a fourth transistor,
the second transistor has a gate electrode coupled to the scanning line,
the third transistor has a gate electrode coupled to a first control line,
the fourth transistor has a gate electrode coupled to a second control line,
the first control line is provided in the first wiring layer and extends in the first direction, and
the second control line is provided in the first wiring layer and extends in the first direction.

8. An electronic apparatus comprising the electro-optical device described in claim 1.
